(19) United States
(12) Patent Application Publication
(10) Pub. No.: US 2015/0329735 A1
(43) Pub. Date: Nov. 19, 2015

(54) COMPOSITION FOR FORMING TRANSPARENT RESIN LAYER, TRANSPARENT RESIN LAYER, SOLID IMAGING ELEMENT AND OPTOELECTRONICS DEVICE

(71) Applicant: FUJIFILM Corporation, Tokyo (JP)

(72) Inventors: Shoichi NAKAMURA, Haibara-gun (JP); Hideki TAKAKUWA, Haibara-gun (JP); Kazuto SHIMADA, Haibara-gun (JP)

(73) Assignee: FUJIFILM Corporation, Tokyo (JP)

(21) Appl. No.: 14/813,265

(22) Filed: Jul. 30, 2015

Related U.S. Application Data
(63) Continuation of application No. PCT/JP2014/054361, filed on Feb. 24, 2014.

(30) Foreign Application Priority Data
Feb. 28, 2013 (JP) 2013-039260
Jul. 8, 2013 (JP) 2013-142767

(51) Int. Cl. C09D 133/10; H01L 33/56; H01L 31/0203

(52) U.S. Cl. CPC C09D 133/10; H01L 31/0203; H01L 33/56

(57) ABSTRACT

A composition for forming a transparent resin layer of the present invention includes a polymerization initiator having a molar absorption coefficient (ε) at a wavelength of 365 nm of 1000 mol⁻¹·L·cm⁻¹ or less; a polymerizable compound; a polymer; and a solvent. The polymerization initiator is preferably at least one selected from the group consisting of an α-hydroxyacetophenone-based compound and a phosphine-based compound.

### CROSS-REFERENCE TO RELATED APPLICATIONS

This application is a Continuation of PCT International Application No. PCT/JP2014/054361 filed on Feb. 24, 2014, which claims priority under 35 U.S.C §119(a) to Japanese Patent Application No. 2013-039260 filed on Feb. 28, 2013 and Japanese Patent Application No. 2013-142767 filed on Jul. 8, 2013. Each of the above application(s) is hereby expressly incorporated by reference, in its entirety, into the present application.

### BACKGROUND OF THE INVENTION

1. Field of the Invention

The present invention relates to a composition for forming a transparent resin layer, a transparent resin layer, a solid imaging element, and an optoelectronics device.

2. Description of the Related Art

In color filters that are used in image sensors (CCD, CMOS, and the like), there are occasions in which white (transparency) is employed as one color of the plural colors of a multicolor color filter for the purpose of increasing sensitivity.

For example, JP2010-078729A discloses a photosensitive resin composition capable of forming white (transparent) pixels. More specifically, a photosensitive resin composition is disclosed, which exhibits excellent resolution even if a pattern is formed at a low amount of exposure (particularly, less than 200 mJ/cm²), and in which deterioration in the formation of a rectangular pattern is suppressed even during post-baking of the subsequent step.

Furthermore, a transparent resin composition accomplishes an important role in the production of optoelectronics devices (see JP2007-524243A).

### SUMMARY OF THE INVENTION

On the other hand, in recent years, regarding the transparent resin layer used in image sensors or optoelectronics devices, transparent resin layers having larger thicknesses (about 25 μm) have been preferred. On the other hand, even in a case in which a transparent resin layer is thick, it is required that the occurrence of coloration at the time of a heating treatment after the formation of a thick film should be suppressed.

The inventors of the present invention formed a thick transparent resin layer capable of patterning by a photolithographic method, using the photosensitive resin composition containing an oxime-based photopolymerization initiator described in JP2010-078729A. A characteristics evaluation was carried out on this thick transparent resin layer, and the occurrence of coloration in the transparent resin layer at the time of a heating treatment after the formation of the thick film was recognized. Thus, it was confirmed that further improvements are needed.

Furthermore, when a thick film is produced using the photosensitive resin composition described in JP2010-078729A, the patterning performance also does not satisfy the level that is necessarily required currently, and further improvements are needed.

Under such circumstances, it is an object of the present invention to provide a composition for forming a transparent resin layer, which is capable of forming a thick transparent resin layer and exhibits excellent patterning performance according to a photolithographic method, and in which the occurrence of coloration at the time of a heating treatment is suppressed.

Furthermore, it is another object of the invention to provide a transparent resin layer obtainable from this composition for forming a transparent resin layer, and a solid imaging device and an optoelectronics device, both of which include this transparent resin layer.

The inventors of the present invention conducted a thorough investigation on the problems of the related arts, and as a result, the inventors found that the problems can be solved by using a predetermined polymerization initiator.

That is, the inventors found that the objects described above can be achieved by the following configuration.

(1) A composition for forming a transparent resin layer, the composition including a polymerization initiator having a molar absorption coefficient (ε) at a wavelength of 365 nm of 1000 mol⁻¹·L·cm⁻¹ or less, a polymerizable compound, a polymer, and a solvent.

(2) The composition for forming a transparent resin layer according to (1), wherein the polymerization initiator does not contain an amino group.

(3) The composition for forming a transparent resin layer according to (1) or (2), wherein the polymerization initiator includes at least one selected from the group consisting of an α-hydroxyacetophenone-based compound and a phosphine-based compound.

(4) The composition for forming a transparent resin layer according to any one of (1) to (3), wherein the polymerization initiator includes both of an α-hydroxyacetophenone-based compound and a phosphine-based compound.

(5) The composition for forming a transparent resin layer according to (4), wherein the phosphine-based compound is included in an amount of 5 to 30 parts by mass relative to 100 parts by mass of the α-hydroxyacetophenone-based compound.

(6) The composition for forming a transparent resin layer according to any one of (1) to (5), includes a polymer formed by polymerizing a monomer component including a compound represented by the following Formula (ED) as a polymer.

(7) The composition for forming a transparent resin layer according to any one of (1) to (6), includes a bifunctional or higher-functional (meth)acrylate compound having at least an acid group as a polymerizable compound.

(8) The composition for forming a transparent resin layer according to any one of (3) to (7), wherein the acetophenone-based compound includes a compound represented by the following Formula (1).

(9) The composition for forming a transparent resin layer according to any one of (3) to (8), wherein the phosphine-based compound includes an acylphosphine oxide.

(10) The composition for forming a transparent resin layer according to any one of (3) to (9), wherein the phosphine-based compound includes a compound selected from the group consisting of a compound represented by the following Formula (2) and a compound represented by the following Formula (3).

(11) The composition for forming a transparent resin layer according to any one of (4) to (10), wherein the polymerization initiator includes at least one selected from the group consisting of 2-hydroxy-2-methyl-1-phenylpropan-1-one, bis(2,4,6-trimethylbenzoyl)phenylphosphine oxide, bis(2,6-dimethoxybenzoyl)-2,4,4-trimethylpentylphosphine oxide, 1-hydroxycyclohexyl phenyl ketone, and diphenyl(2,4,6-trimethylbenzoyl)phosphine oxide.

(12) The composition for forming a transparent resin layer according to any one of (1) to (11), further including at least one selected from the group consisting of an ultraviolet absorber, an adhesion improving agent, a polymerization inhibitor, and a surfactant.

(13) The composition for forming a transparent resin layer according to any one of (1) to (12), wherein the content of the solvent is 0% by mass to 45% by mass relative to the total mass of the composition for forming a transparent resin layer.

(14) A transparent resin layer formed by curing the composition for forming a transparent resin layer according to any one of (1) to (13).

(15) A solid imaging element including a transparent resin layer formed by curing the composition for forming a transparent resin layer according to any one of (1) to (13).

(16) An optoelectronics device including a transparent resin layer formed by curing the composition for forming a transparent resin layer according to any one of (1) to (13).

According to the invention, a composition for forming a transparent resin layer, which has excellent patterning performance according to a photolithographic method, has the occurrence of coloration suppressed at the time of a heating treatment, and is capable of forming a thick transparent resin layer, can be provided.

Furthermore, according to the invention, a transparent resin layer that is obtained from this composition for forming a transparent resin layer, and a solid imaging element and an optoelectronics device, both of which include this transparent resin layer, can also be provided.

### BRIEF DESCRIPTION OF THE DRAWING

FIG. 1 is a diagram illustrating one aspect of optoelectronics device which uses a transparent resin layer of the invention.

### DESCRIPTION OF THE PREFERRED EMBODIMENTS

Hereinafter, suitable aspects of the composition for forming a transparent resin layer, the transparent resin layer, the solid imaging element, and the optoelectronics device of the invention will be described in detail.

A numerical value range indicated using “to” in the present specification means a range including the values described before and after “to” as the lower limit and the upper limit.

In regard to the descriptions of a group (atomic group) in the present specification, a description which does not indicate the state of being substituted or unsubstituted is intended to include such a group having a substituent as well as such a group that does not have a substituent. For example, an “alkyl group” includes an alkyl group which does not have a substituent (unsubstituted alkyl group) as well as an alkyl group which has a substituent (substituted alkyl group).

First, the various components (polymerization initiator, polymerizable compound, polymer, and the like) included in the composition for forming a transparent resin layer (hereinafter, may be simply referred to as “composition”) will be described in detail below, and then the transparent resin layer and the solid imaging element will be described in detail.

(Polymerization Initiator)

The composition for forming a transparent resin layer includes a polymerization initiator having a molar absorption coefficient (ε) at a wavelength of 365 nm of 1000 mol⁻¹·L·cm⁻¹ or less. With this polymerization initiator, the absorption edge lies on the shorter wavelength side, and even in a case in which the coating film formed from the composition for forming a transparent resin layer is thick, the decrease in the transmissivity is suppressed.

The molar absorption coefficient (ε) at a wavelength of 365 nm of the polymerization initiator is 1000 mol⁻¹·L·cm⁻¹ or less, and from the viewpoint that transparency can be secured, the molar absorption coefficient is preferably 950 mol⁻¹·L·cm⁻¹ or less, and more preferably 900 mol⁻¹·L·cm⁻¹ or less. The lower limit is not particularly limited thereto; however, the lower limit is usually 5 mol⁻¹·L·cm⁻¹ or more in many cases.

If the molar absorption coefficient (ε) at a wavelength of 365 nm is more than 1000 mol⁻¹·L·cm⁻¹, the absorption edge reaches to the visible region, and this causes coloration.

In regard to the method for measuring the molar absorption coefficient (ε), the polymerization initiator is dissolved in a solvent (particularly, acetonitrile is preferred), the absorbance at a wavelength of 365 nm is measured using a UV-Vis-NIR spectrometer manufactured by Agilent Technologies, Inc. (CARY 5000), and the molar absorption coefficient (ε) is determined by the formula: A=εLc (wherein A represents the absorbance; ε represents the molar absorption coefficient (mol⁻¹·L·cm⁻¹); c represents the concentration (mol/L) of the analyte in the solution; and L represents the optical path length (cm)).

Specific examples of the polymerization initiator include halogenated hydrocarbon derivatives (for example, a derivative having a triazine skeleton and a derivative having an oxadiazole skeleton), phosphine-based compounds including an acylphosphine compound, hexaarylbiimidazole, oxime compounds such as a keto oxime ether, organic peroxides, thio compounds, ketone compounds such as acetophenones, aromatic onium salts, aminoacetophenone compounds, hydroxyacetophenone, ketal compounds, benzoin compounds, acridine compounds, azo compounds, coumarin compounds, azide compounds, metallocene compounds, organic boric acid compounds, disulfonic acid compounds, and alkylamino compounds.

Among them, a polymerization initiator which does not contain an amino group is preferred as the polymerization initiator, from the viewpoint that yellowing caused by light exposure or heat does not easily occur, and the decrease in the transmissivity of the transparent resin layer is suppressed.

Here, an amino group is a generic name including a primary amino group, a secondary amino group (—NH—), and a tertiary amino group (−N<).

Furthermore, from the viewpoint that yellowing caused by light exposure or heat does not easily occur, and the decrease in the transmissivity of the transparent resin layer is suppressed, it is preferable that at least one polymerization initiator selected from the group consisting of an acetophenone-based compound (acetophenone-based polymerization initiator) and a phosphine-based compound (phosphine-based polymerization initiator) is included as the polymerization initiator.

Meanwhile, among acetophenone-based compounds, an α-hydroxyacetophenone-based compound is preferred because the compound is not likely to be subject to oxidative damage and is not easily discolored by heat. Furthermore, in the case of using an acetophenone-based compound, it is preferable because when the transparent resin layer is heat treated, the generation of cracks is further suppressed.

Among them, from the viewpoint that discoloration caused by heat does not easily occur, and the pattern shape is superior when a pattern is formed, an embodiment of using an acetophenone-based compound and a phosphine-based compound in combination is preferred.

The phosphine-based compound is preferably included in an amount of 5 to 30 parts by mass, and more preferably in an amount of 5 to 25 parts by mass, with respect to 100 parts by mass of the acetophenone-based compound (particularly, the α-hydroxyacetophenone-based compound). Thereby, coloration is suppressed when a thick film is formed, and a transparent resin layer having higher sensitivity can be formed compared with the case of using the acetophenone-based compound alone. Furthermore, still another initiator may also be used to the extent that the performance described above is not impaired, and a third initiator or a fourth initiator can be used in addition to the combined use of the acetophenone-based compound and the phosphine-based compound.

The acetophenone-based compound and the phosphine-based compound are described in detail below.

(Acetophenone-Based Compound)

Specific examples of the acetophenone-based compound include 2,2-diethoxyacetophenone, p-dimethylaminoacetophenone, 2-hydroxy-2-methyl-1-phenylpropan-1-one, p-dimethylaminoacetophenone, 4′-isopropyl-2-hydroxy-2-methylpropiophenone, 1-hydroxycyclohexyl phenyl ketone, 2-benzyl-2-dimethylamino-1-(4-morpholinophenyl)-butan-1-one, 2-tolyl-2-dimethylamino-1-(4-morpholinophenyl)-butan-1-one, 2-methyl-1-[4-(methylthio)phenyl]-2-morpholinopropan-1-one, 2-methyl-1-(4-methylthiophenyl)-2-morpholinopropan-1-one, 2-benzyl-2-dimethylamino-1-(4-morpholinophenyl)-butan-1-one, 2-(dimethylamino)-2-[(4-methylphenyl)methyl]-1-[4-(4-morpholinyl)phenyl]-1-butanone, and 2-methyl-1-(4-methylthiophenyl)-2-morpholinopropan-1-one.

Among them, an α-hydroxyacetophenone-based compound is more preferred from the viewpoint that superior effects of the invention are obtained.

Examples of the α-hydroxyacetophenone-based compound include, in addition to those described above, 2-hydroxy-2-methyl-1-phenylpropan-1-one (Darocur 1173), 1-[4-(2-hydroxyethoxy)phenyl]-2-hydroxy-2-methyl-1-propan-1-one (IRGACURE 2959), 2-hydroxy-1-(4-(4-(2-hydroxy-3,5,2-methylpropionyl)benzyl)phenyl)-2-methylpropan-1-one, and 1-hydroxycyclohexyl phenyl ketone (IRGACURE 184).

A suitable embodiment of the α-hydroxyacetophenone-based compound is a compound represented by Formula (1):

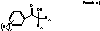

In Formula (1), R₁₁ and R₁₂ each independently represent a hydrogen atom, an alkoxy group, or an alkyl group which may have a substituent. Among these, it is preferable that R₁₁ and R₁₂ are both alkyl groups, or R₁₁ and R₁₂ are bonded to each other and form a ring structure.

The alkyl group in the alkoxy group may be a linear, branched, or cyclic alkyl group, and the number of carbon atoms of the alkyl group is preferably 1 to 30, and more preferably 1 to 20. Examples of the alkoxy group include a methoxy group, an ethoxy group, a propoxy group, and a butoxy group.

The alkyl group may be a linear, branched, or cyclic alkyl group, and the number of carbon atoms of the alkyl group is preferably 1 to 30, more preferably 1 to 20, and even more preferably 1 to 5.

The alkyl group may further have a substituent. Regarding the kind of the substituent, examples include the substituents described in paragraph <0173> of JP2010-106268A (paragraph <0205> of corresponding US2011/0124824A), the disclosure of which is incorporated in the present specification.

R₁₁ and R₁₂ may be bonded to each other and form a ring structure. The ring structure to be formed is not particularly limited thereto, and may be a monocyclic structure or a polycyclic structure. An example thereof is a cycloalkyl group having 3 to 20 carbon atoms. Preferred is a monocyclic or polycyclic cycloalkyl group having 3 to 10 carbon atoms.

R₁₃ represents a hydrocarbon group which may contain a heteroatom.

A hydrocarbon group is a group containing carbon atoms and hydrogen atoms, and more specific examples thereof include an aliphatic hydrocarbon group, an aromatic hydrocarbon group, and a group combining these. The aliphatic hydrocarbon group may be any of a linear group, a branched group, or a cyclic group.

The hydrocarbon group may contain a heteroatom. That is, the hydrocarbon group may be a heteroatom-containing hydrocarbon group. There are no particular limitations on the kind of the heteroatom to be contained, but examples thereof include a halogen atom, an oxygen atom, a nitrogen atom, a sulfur atom, a selenium atom, and a tellurium atom.

Preferred embodiments of R₁₃ include an alkyl group, —S—R_{d}, and —N(R_{d})₂. Meanwhile, R_{d} represents an alkyl group (preferably having 1 to 3 carbon atoms).

When there are a large number of R₁₃, R₁₃'S may be respectively identical to or different from each other. The alkyl group as used herein has the same meaning as the alkyl group represented by R₁₁ or R₁₂ described above.

n represents an integer from 0 to 5. Among others, n is preferably 0 to 4, and more preferably 0.

(Phosphine-Based Compound)

A phosphine-based compound is intended to mean a compound containing a phosphorus atom (P).

The phosphine-based compound is particularly preferably an acylphosphine oxide-based compound.

The acylphosphine oxide-based compound will be described in detail below.

Examples of the acylphosphine oxide-based compound include a monoacylphosphine oxide compound, and a bisacylphosphine oxide compound. More specific examples thereof include 2,4,6-trimethylbenzoyl-diphenylphosphine oxide (commercially available products include Darocur TPO), 2,4,6-triethylbenzoyl-diphenylphosphine oxide, 2,4,6-triphenylbenzoyl-diphenylphosphine oxide, bis(2,4,6-trimethylbenzoyl)-phenylphosphine oxide (commercially available products include IRGACURE 819), and bis(2,6-dimethoxybenzoyl)-2,4,4-trimethylpentylphosphine oxide (commercially available products include CGI 403).

A suitable embodiment of the acylphosphine oxide-based compound is a compound represented by Formula (2) or a compound represented by Formula (3).

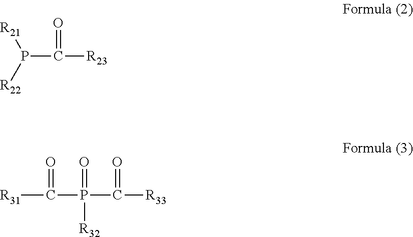

In Formula (2), R₂₁ and R₂₂ each independently represent an aliphatic group, an aromatic group, an aliphatic oxy group, an aromatic oxy group, or a heterocyclic group. R₂₃ represents an aliphatic group, an aromatic group, or a heterocyclic group. Each of R₂₁ to R₂₃ may further have a substituent.

Meanwhile, the aliphatic group, aromatic group, aliphatic oxy group, aromatic oxy group, or heterocyclic group may have a substituent. The substituent as used herein has the same meaning as the substituent described above in connection with Formula (1).

Examples of the aliphatic group include an alkyl group, an alkenyl group, an alkynyl group, and an aralkyl group. Furthermore, the aliphatic group may be a cyclic aliphatic group, or a chain-like aliphatic group. The chain-like aliphatic group may be branched. The number of carbon atoms contained in the aliphatic group is preferably 2 to 30, and more preferably 2 to 20.

Examples of the aromatic group include an aryl group and a substituted aryl group. The number of carbon atoms of the aryl group is preferably 6 to 30, and more preferably 6 to 20.

Examples of the aliphatic oxy group include an alkoxy group, an alkenyloxy group, an alkynyloxy group, and an aralkyloxy group, all of which may be substituted or unsubstituted. Preferred is a substituted or unsubstituted alkoxy group having 1 to 30 carbon atoms.

Examples of the aromatic oxy group include a substituted or unsubstituted aryloxy group, and a substituted or unsubstituted aryloxy group having 6 to 30 carbon atoms is preferred.

The heterocyclic group is preferably a heterocyclic group containing a N, O or S atom, and examples thereof include a pyridyl group, a furyl group, a thienyl group, an imidazolyl group, and a pyrrolyl group.

In Formula (3), R₃₁ and R₃₃ each independently represent an alkyl group, an aryl group, or a heterocyclic group. Furthermore, R₃₂ represents an alkyl group, an aryl group, an alkoxy group, an aryloxy group, or a heterocyclic group.

The various groups represented by R₃₁ to R₃₃ as used herein respectively have the same meanings as the various groups of Formula (1) and Formula (2) described above. In addition, each of R₃₁ to R₃₃ may further have a substituent. The substituent as used herein has the same meaning as the substituent described in connection with Formula (1).

Furthermore, examples of the acylphosphine oxide-based compound represented by Formula (2) or Formula (3) include the compounds described in Table 1 on pages 7 to 9 of JP1998-40799B (JP-S63-40799B) (Table 1 described in U.S. Pat. No. 4,324,744A).

Examples of an embodiment of using the acetophenone-based compound and the phosphine-based compound in combination include IRGACURE 1800.

An optimal embodiment of the polymerization initiator includes at least one selected from the group consisting of 2-hydroxy-2-methyl-1-phenylpropan-1-one, bis(2,4,6-trimethylbenzoyl)-phenylphosphine oxide, bis(2,6-dimethoxybenzoyl)-2,4,4-trimethylpentylphosphine oxide, 1-hydroxycyclohexyl phenyl ketone, and diphenyl(2,4,6-trimethylbenzoyl)phosphine oxide, from the viewpoint that superior effects of the invention are obtained. Two or more kinds of these compounds may be included.

The polymerization initiator may be used singly, or in combination of two or more kinds.

The content of the polymerization initiator (in the case of having two or more kinds, the total content) included in the composition for forming a transparent resin layer is not particularly limited; however, the content is preferably 0.1% to 50% by mass, more preferably 0.5% to 30% by mass, and even more preferably 1% to 20% by mass, with respect to the total solid content of the composition for forming a transparent resin layer. When the content is in this range, satisfactory sensitivity and pattern forming properties are obtained, and also, the transparent resin layer has superior transparency.

Meanwhile, the total solid content is intended to mean the total amount of components excluding the components that do not constitute the transparent resin layer, such as a solvent.

(Polymerizable Compound)

The composition for forming a transparent resin layer includes a polymerizable compound.

There are no limitations on the kind of the polymerizable compound, and examples thereof include a cationic polymerizable compound and a radical polymerizable compound; however, from the viewpoint of reactivity, a radical polymerizable compound is more preferred. Examples of the polymerizable group contained in the polymerizable compound include an ethylenically unsaturated bond (for example, a (meth)acryloyloxy group, a (meth)acrylamide group, a styryl group, a vinyl group of a vinyl ester or a vinyl ether, or an allyl group of an allyl ether or an allyl ester), and a cyclic ether group capable of polymerization (for example, an epoxy group, or an oxetane group).

Meanwhile, a (meth)acryloyloxy group means an acryloyloxy group or a methacryloyloxy group, and a (meth)acrylamide group means an acrylamide group or a methacrylamide group. Furthermore, according to the present specification, the term “(meth)” as used in (meth)acrylate, (meth)acrylic acid and the like also has the same meaning.

A suitable embodiment of the polymerizable compound is a bifunctional or higher-functional (meth)acrylate compound having at least an acid group (hereinafter, also referred to as acid group-containing compound).

The acid group-containing compound is preferably, for example, a compound represented by the following Formula (4):

(A)ₙ₁-L-(Ac)ₙ₂ Formula (4)

In Formula (4), A represents an acid group; L represents a group having the valence of (n1+n2), which is composed of two or more kinds of atoms selected from an oxygen atom, a carbon atom, and a hydrogen atom; and Ac represents a (meth)acryloyloxy group. n1 represents an integer from 1 to 3, and n2 represents an integer of 2 or larger.

Examples of the acid group represented by A include a carboxylic acid group, a sulfonamide group, a phosphonic acid group, and a sulfonic acid group, and a carboxylic acid group is preferred.

L is preferably a group containing at least carbon atoms and hydrogen atoms. The total number of the carbon atoms and oxygen atoms that constitute L is preferably 3 to 15, and more preferably 6 to 12.

n1 is preferably 1 or 2, and more preferably 1. n2 is preferably an integer of 6 or less, more preferably an integer from 2 to 5, and even more preferably 3 or 4.

Suitable embodiments of the acid group-containing compound include compounds represented by the following Formulas (5-1) to (5-4):

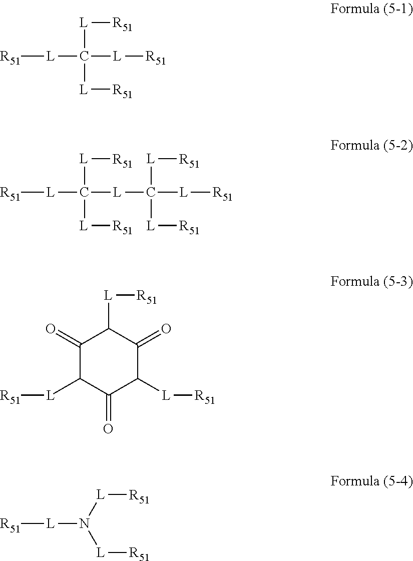

In Formulas (5-1) to (5-4), R₅₁ represents a (meth)acryloyloxy group or an acid group. Examples of the acid group include a carboxylic acid group, a sulfonamide group, a phosphonic acid group, and a sulfonic acid group.

In Formula (5-1), two or three of R₅₁ represent (meth)acryloyloxy groups, and one or two of R₅₁ represent acid groups.

In Formula (5-2), three to five of R₅₁ represent (meth)acryloyloxy groups, and one to three of R₅₁ represent acid groups.

In Formulas (5-3) and (5-4), two of R₅₁ represent (meth)acryloyloxy groups, and one of R₅₁ represents an acid group.

L represents a divalent linking group. Examples of the divalent linking group include a divalent aliphatic hydrocarbon group (preferably having 1 to 8 carbon atoms, and more preferably having 1 to 5 carbon atoms), a divalent aromatic hydrocarbon group (preferably having 6 to 12 carbon atoms), —O—, —S—, —SO₂—, —N(R)— (wherein R represents an alkyl group), —CO—, —NH—, —COO—, —CONH—, and groups combining these groups.

Examples of the divalent aliphatic hydrocarbon group (for example, an alkylene group) include a methylene group, an ethylene group, a propylene group, and a butylene group.

Examples of the divalent aromatic hydrocarbon group include a phenylene group and a naphthylene group. Meanwhile, L is preferably a divalent aliphatic hydrocarbon group, —O—, —COO—, or a group combining these. Examples of the combined group include —(CH₂)ₚ—COO—(CH₂)ₚ— and —(CH₂)ₚ—O—. p represents an integer from 1 to 3.

Among all the polymerizable compounds, the proportion of the acid group-containing compound is preferably 1% to 60% by mass, more preferably 1% to 50% by mass, even more preferably 1% to 20% by mass, and particularly preferably 1.5% to 15% by mass.

The acid group-containing compound may be used singly, or in combination of two or more kinds. When the acid group-containing compound includes two or more kinds, the total amount is in the range described above.

The composition for forming a transparent resin layer may include a polymerizable compound other than the acid group-containing compound (hereinafter, may be referred to as “other polymerizable compound”), and it is preferable that the composition includes such a polymerizable compound.

Specifically, the other polymerizable compound is selected from compounds having at least one, and preferably two or more, terminal ethylenically unsaturated bonds. The group of such compounds is widely known in the pertinent industrial fields, and these can be used in the invention without any particular limitations. These compounds may be in any chemical form, for example, a monomer, a prepolymer, that is, a dimer, a trimer or an oligomer, a mixture thereof and multimers thereof; however, a monomer is preferred.

More specific examples of the monomer and a prepolymer thereof include unsaturated carboxylic acids (for example, acrylic acid, methacrylic acid, itaconic acid, crotonic acid, isocrotonic acid, and maleic acid) and esters thereof; amides; and multimers thereof. Preferred examples include an ester of an unsaturated carboxylic acid and a polyhydric aliphatic alcohol compound, an amide of an unsaturated carboxylic acid and a polyhydric aliphatic amine compound, and a multimer thereof. Furthermore, an addition reaction product of an unsaturated carboxylic acid ester or amide having a nucleophilic substituent such as a hydroxyl group, an amino group or a mercapto group and a monofunctional or polyfunctional isocyanate or epoxy compound; or a dehydration condensation product of such an unsaturated carboxylic acid ester or amide and a monofunctional or polyfunctional carboxylic acid, is also suitably used. Furthermore, an addition reaction product of an unsaturated carboxylic acid ester or amide having an electrophilic substituent such as an isocyanate group or an epoxy group and a monofunctional or polyfunctional alcohol, amine or thiol; and a substitution reaction product of an unsaturated carboxylic acid ester or amide having an eliminable substituent such as a halogen group or a tosyloxy group and a monofunctional or polyfunctional alcohol, amine or thiol, are also suitable. As another example, a group of compounds in which the unsaturated carboxylic acid is replaced with an unsaturated phosphonic acid, a vinylbenzene derivative such as styrene, a vinyl ether, an allyl ether or the like, can also be used.

Regarding these specific compounds, the compounds described in paragraph 0095 to paragraph 0108 of JP2009-288705A can also be suitably used in the invention.

Furthermore, regarding the polymerizable compound, a compound which has an ethylenically unsaturated group having a boiling point of 100° C. or higher at normal pressure and has at least one ethylene group capable of addition polymerization, is also preferred. Examples thereof include monofunctional acrylates and methacrylates such as polyethylene glycol mono(meth)acrylate, polypropylene glycol mono(meth)acrylate, and phenoxyethyl (meth)acrylate; polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl) ether, tri(acryloyloxyethyl) isocyanurate, a product obtained by adding ethylene oxide or propylene oxide to a polyfunctional alcohol such as glycerin or trimethylolethane and then converting the resultant to a (meth)acrylate, urethane (meth)acrylates, polyester acrylates, polyfunctional acrylates or methacrylates such as an epoxy acrylate which is a reaction product of an epoxy resin and (meth)acrylic acid, and mixtures thereof.

Other examples include a polyfunctional (meth)acrylate obtainable by causing a polyfunctional carboxylic acid to react with a compound having a cyclic ether group and an ethylenically unsaturated group, such as gycidyl (meth)acrylate.

Furthermore, as another preferred polymerizable compound, a compound having a fluorene ring and having ethylenically polymerizable groups with bifunctionality or higher-functionality, and a cardo resin can also be used.

Furthermore, suitable examples of the compound which has a boiling point of 100° C. or higher at normal pressure and carries at least one ethylenically unsaturated group capable of addition polymerization include the compounds described in paragraphs <0254> to <0257> of JP2008-292970A (paragraphs <0272> to <0276> of corresponding US2008/8076044A), the disclosure of which is incorporated herein.

In addition to the compounds described above, as the polymerizable compound, a radical polymerizable monomer represented by the following formulas (MO-1) to (MO-5) can also be suitably used. In the formulas, when T is an oxyalkylene group, the end on the carbon atom side is bonded to R.

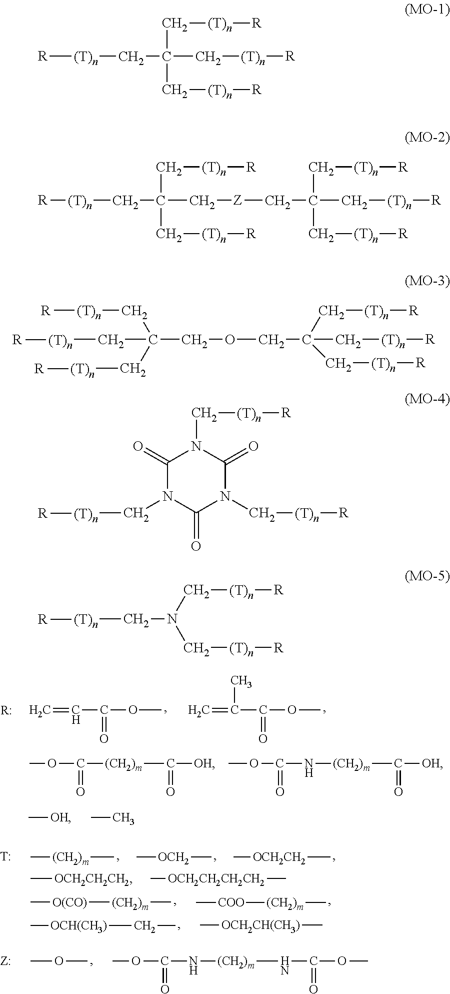

In the general formulas, n is from 0 to 14, and m is from 1 to 8. R and T that are present in plural numbers in one molecule may be respectively identical with or different from each other.

In each of the radical polymerizable monomers represented by Formulas (MO-1) to (MO-5), at least one of plural R's represents a group represented by —OC(═O)CH═CH₂ or —OC(═O)C(CH₃)═CH₂.

Meanwhile, in Formulas (MO-1) to (MO-5), when at least one of R's represents —OCO—(CH₂)ₘ—COOH or —OCONH—(CH₂)ₘ—COOH, the compound corresponds to the acid group-containing compound described above, and the compound is also preferably used as the acid group-containing compound.

Regarding specific examples of the radical polymerizable monomer represented by Formulas (MO-1) to (MO-5), those compounds described in paragraph 0248 to paragraph 0251 of JP2007-269779A can be suitably used.

Furthermore, a compound produced by adding ethylene oxide or propylene oxide to a polyfunctional alcohol and then converting the resultant to a (meth)acrylate, which is described together with specific examples thereof as Formulas (1) and (2) in JP1998-62986A (JP-H10-62986A), can also be used as the polymerizable compound.

Regarding the polymerizable compound, dipentaerythritol triacrylate (commercially available products include KAYARAD D-330; manufactured by Nippon Kayaku Co., Ltd.), dipentaerythritol tetraacrylate (commercially available products include KAYARAD D-320; manufactured by Nippon Kayaku Co., Ltd.), dipentaerythritol penta(meth)acrylate (commercially available products include KAYARAD D-310; manufactured by Nippon Kayaku Co., Ltd.), dipentaerythritol hexa(meth)acrylate (commercially available products include KAYARAD DPHA; manufactured by Nippon Kayaku Co., Ltd.), and structures in which the (meth)acryloyl groups of these compounds are interrupted by ethylene glycol or propylene glycol residues, are also preferred. Oligomer type compounds of these compounds can also be used.

Furthermore, the polymerizable compound is a polyfunctional monomer (polyfunctional polymerizable compound), and may have an acid group such as a carboxyl group, a sulfonic acid group, or a phosphoric acid group (monomer having an acid group). Therefore, when an ethylenic compound is a compound having an unreacted carboxyl group as in the case of a mixture as described above, this ethylenic compound can be directly used. However, if necessary, an acid group may be introduced by causing a hydroxyl group of the ethylenic compound to react with a non-aromatic carboxylic acid anhydride. In this case, specific examples of the non-aromatic carboxylic acid anhydride that can be used include tetrahydrophthalic anhydride, alkylated tetrahydrophthalic anhydride, hexahydrophthalic anhydride, alkylated hexahydrophthalic anhydride, succinic anhydride, and maleic anhydride.

The monomer having an acid group is an ester of an aliphatic polyhydroxy compound and an unsaturated carboxylic acid, and a polyfunctional monomer produced by causing an unreacted hydroxyl group of an aliphatic polyhydroxy compound to react with a non-aromatic carboxylic acid anhydride and introducing an acid group to the resultant, is preferred. A particularly preferred example is this ester in which the aliphatic polyhydroxy compound is pentaerythritol and/or dipentaerythritol. Examples of commercially available products include polybasic acid-modified acrylic oligomers M-510 and M-520 manufactured by Toagosei Co., Ltd.

The acid value of the polyfunctional monomer having an acid group is preferably 0.1 to 40 mgKOH/g, and particularly preferably 5 to 30 mg KOH/g. If the acid value of the polyfunctional monomer is too low, the developing dissolution characteristics are deteriorated. If the acid value is too high, production or handling becomes difficult, the photopolymerization performance is deteriorated, and curing properties such as surface smoothness of pixels are deteriorated. Therefore, in the case of using two or more kinds of polyfunctional monomers having different acid groups in combination, or in the case of using a polyfunctional monomer that does not have an acid group in combination, it is preferable to adjust the acid groups of the polyfunctional monomers as a whole to be in the range described above.

Other examples of the polymerizable compound include the polymerizable compounds described above in, for example, paragraphs <0481> to <0490> of JP2012-208494A (paragraphs <0589> to <0600> of corresponding US2012/235099A), the disclosure of which is incorporated herein.

Other examples of the polymerizable compound include polyfunctional monomers having a caprolactone structure (for example, DPCA-20, DPCA-30, DPCA-60, and DPCA-120 marketed as KAYARAD DPCA series from Nippon Kayaku Co., Ltd.), and urethane oligomers (UAS-10, UAB-140 (manufactured by Sanyo Kokusaku Pulp Co., Ltd.), UA-7200 (manufactured by Shin Nakamura Chemical Co., Ltd.), DPHA-40 (manufactured by Nippon Kayaku Co., Ltd.), and UA-306H, UA-306T, UA-306I, AH-600, T-600, and M-600 (manufactured by Kyoeisha Chemical Co., Ltd.)).

In regard to these polymerizable compounds, the details of the structure, the matter of single use or combined use, and the method of use such as the amount of addition can be arbitrarily set in accordance with the final performance design of the composition for forming a transparent resin layer. For example, from the viewpoint of sensitivity, a structure having a large content of unsaturated groups per molecule is preferred, and in many cases, a bifunctional or higher-functional structure is preferred. Furthermore, from the viewpoint of increasing the strength of a cured film, a structure with trifunctionality or higher functionality is desirable, and a method of regulating both sensitivity and strength by using structures having different functionalities and different polymerizable groups (for example, acrylic acid esters, methacrylic acid esters, styrene-based compounds, and vinyl ether-based compounds) in combination is also effective. Furthermore, when trifunctional or higher-functional polymerizable compounds having different ethylene oxide chain lengths are used in combination, developability of the composition for forming a transparent resin layer can be regulated, and it is preferable from the viewpoint that excellent pattern forming ability is obtained. Furthermore, in regard to the compatibility with the other components included in the composition (for example, a photopolymerization initiator, a colorant (pigment), and a binder polymer) and dispersibility as well, the selection of the polymerizable compound and the method of use are important factors, and for example, compatibility can be enhanced by using a low purity compound or using two or more kinds in combination. Furthermore, a particular structure can also be selected from the viewpoint of enhancing the adhesiveness to a hard surface of a substrate or the like.

The content of the polymerizable compound in the composition for forming a transparent resin layer is not particularly limited; however, from the viewpoint of having superior effects of the invention, the content is preferably 10% to 80% by mass, and more preferably 30% to 70% by mass, with respect to the total solid content of the composition for forming a transparent resin layer.

(Polymer)

The composition for forming a transparent resin layer includes a polymer.

There are no particular limitations on the kind of the polymer; however, from the viewpoint of developability, the polymer is preferably an alkali-soluble resin.

The alkali-soluble resin can be appropriately selected from alkali-soluble resins that are linear organic high molecular weight polymers and have at least one group which promotes alkali-solubility in the molecule (preferably, a molecule having an acrylic copolymer or a styrene-based copolymer as the main chain). From the viewpoint of heat resistance, a polyhydroxystyrene-based resin, a polysiloxane-based resin, an acrylic resin, an acrylamide-based resin, and an acryl/acrylamide copolymer resin are preferred, and from the viewpoint of controlling developability, an acrylic resin, an acrylamide-based resin, and an acryl/acrylamide copolymer resin are preferred.

Examples of the group that promotes alkali-solubility (hereinafter, also called an acid group) include a carboxyl group, a phosphoric acid group, a sulfonic acid group, and a phenolic hydroxyl group; however, any group which is soluble in an organic solvent and is capable of developing by a weak aqueous alkali solution is preferred, and (meth)acrylic acid is particularly preferred. These acid groups may be used singly or in combination of two or more kinds thereof.

Examples of the monomer that can provide an acid group after polymerization include a monomer having a hydroxyl group, such as 2-hydroxyethyl (meth)acrylate; a monomer having an epoxy group, such as glycidyl (meth)acrylate; and a monomer having an isocyanate group, such as 2-isocyanatoethyl (meth)acrylate. These monomers for introducing an acid group may be used singly or in combination of two or more kinds thereof. In order to introduce an acid group to an alkali-soluble binder, for example, a monomer having an acid group and/or a monomer capable of providing an acid group after polymerization (hereinafter, may be referred to as “monomer for introducing an acid group”) may be polymerized as a monomer component.

One suitable embodiment of the polymer is a polymer formed by polymerizing monomer components including a compound represented by the following Formula (ED). When a polymer formed by polymerizing monomer components including a compound represented by Formula (ED) (hereinafter, also referred to as “ether dimer”) is included, the composition of the invention can form a cured coating film having superior heat resistance and transparency.

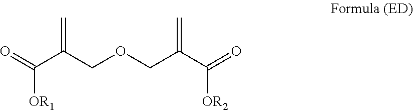

In Formula (E), R₁ and R₂ each represent a hydrogen atom or a hydrocarbon group having 1 to 25 carbon atoms which may have a substituent.

The hydrocarbon group represented by R₁ and R₂ which has 1 to 25 carbon atoms and may have a substituent is not particularly limited, but examples thereof include a linear or branched alkyl group; an aryl group; an alicyclic hydrocarbon group; an alkyl group substituted with an alkoxy group; and an alkyl group substituted with an aryl group. Among these, particularly, a substituent of primary or secondary carbon that is not easily eliminated by acid or heat, such as a methyl group, an ethyl group, a cyclohexyl group, or a benzyl group, is preferred in view of heat resistance.

Specific examples of the ether dimer include the specific examples of the ether dimer described in paragraph <0565> of JP2012-208494A (<0694> of corresponding US2012/235099A), the disclosure of which is incorporated herein. Preferred examples of the ether dimer include dimethyl-2,2′-[oxybis(methylene)]bis-2-propenoate, diethyl-2,2′-[oxybis(methylene)]bis-2-propenoate, dicyclohexyl-2,2′-[oxybis(methylene)]bis-2-propenoate, and dibenzyl-2,2′-[oxybis(methylene)]bis-2-propenoate. These ether dimers may be used singly or in combination of two or more kinds thereof. The structure derived from a compound represented by Formula (ED) may be copolymerized with other monomers.

According to the invention, it is preferable that the proportion of the ether dimer-derived constituent unit is 1% to 50% by mole, and more preferably 1% to 20% by mole.

The ether dimer may be copolymerized with other monomers.

Examples of the other monomers that can be copolymerized with the ether dimer include a monomer for introducing an acid group, a monomer for introducing a radical polymerizable double bond, a monomer for introducing an epoxy group, and any copolymerizable monomer other than these. These monomers may be used singly or in combination of two or more kinds thereof.

Examples of the monomer for introducing an acid group include a monomer having a carboxyl group, such as (meth)acrylic acid or itaconic acid; a monomer having a phenolic hydroxyl group, such as N-hydroxyphenylmaleimide; and a monomer having a carboxylic acid anhydride group, such as maleic anhydride or itaconic anhydride. Among these, (meth)acrylic acid is particularly preferred.

Furthermore, the monomer for introducing an acid group may be a monomer which can provide an acid group after polymerization, and examples thereof include a monomer having a hydroxyl group, such as 2-hydroxyethyl (meth)acrylate; a monomer having an epoxy group, such as glycidyl (meth)acrylate; and a monomer having an isocyanate group, such as 2-isocyanatoethyl (meth)acrylate. In a case in which a monomer capable of providing an acid group after polymerization is used, it is necessary to perform a treatment for providing an acid group after polymerization.

The treatment for providing an acid group after polymerization may vary depending on the kind of the monomer, and for example, the following treatments may be employed. In the case of using a monomer having a hydroxyl group, for example, a treatment of adding an acid anhydride such as succinic anhydride, tetrahydrophthalic anhydride, or maleic anhydride may be used. In the case of using a monomer having an epoxy group, for example, a treatment of adding a compound having an amino group and an acid group, such as N-methylaminobenzoic acid or N-methylaminophenol, or for example, a treatment of adding an acid anhydride such as, for example, succinic anhydride, tetrahydrophthalic anhydride, or maleic anhydride, to a hydroxyl group generated after adding an acid such as (meth)acrylic acid, may be used. In the case of using a monomer having an isocyanate group, for example, a treatment of adding a compound having a hydroxyl group and an acid group, such as 2-hydroxybutyric acid, may be used.

In a case in which a polymer formed by polymerizing monomer components including a compound represented by Formula (ED) includes a monomer for introducing an acid group, the percentage content of the monomer is not particularly limited; however, the percentage content is preferably 5% to 70% by mass, and more preferably 10% to 60% by mass with respect to the total amount of the monomer components.

Examples of the monomer for introducing a radical polymerizable double bond include a monomer having a carboxyl group, such as (meth)acrylic acid or itaconic acid; a monomer having a carboxylic acid anhydride group, such as maleic anhydride or itaconic anhydride; and a monomer having an epoxy group, such as glycidyl (meth)acrylate, 3,4-epoxycyclohexylmethyl (meth)acrylate, or o- (or m- or p-)vinylbenzyl glycidyl ether. In the case of using a monomer for introducing a radical polymerizable double bond, it is necessary to perform a treatment for providing a radical polymerizable double bond after polymerization. The treatment for providing a radical polymerizable double bond after polymerization may vary depending on the kind of the monomer that is used to provide a radical polymerizable double bond, and for example, the following treatments may be employed. In the case of using a monomer having a carboxyl group, such as (meth)acrylic acid or itaconic acid, a treatment of adding a compound having an epoxy group and a radical polymerizable double bond, such as glycidyl (meth)acrylate, 3,4-epoxycyclohexylmethyl (meth)acrylate, or o- (or m- or p-)vinylbenzyl glycidyl ether, may be employed. In the case of using a monomer having a carboxylic acid anhydride group, such as maleic anhydride or itaconic anhydride, a treatment of adding a compound having a hydroxyl group and a radical polymerizable double bond, such as 2-hydroxyethyl (meth)acrylate, may be employed. In the case of using a monomer having an epoxy group, such as glycidyl (meth)acrylate, 3,4-epoxycyclohexylmethyl (meth)acrylate, or o- (or m- or p-)vinylbenzyl glycidyl ether, a treatment of adding a compound having an acid group and a radical polymerizable double bond, such as (meth)acrylic acid, may be employed.

In a case in which the polymer formed by polymerizing monomer components including a compound represented by Formula (ED) includes a monomer for introducing a radical polymerizable double bond, the percentage content of the monomer is not particularly limited; however, the percentage content is preferably 5% to 70% by mass, and more preferably 10% to 60% by mass, with respect to the total amount of the monomer components.

Examples of the monomer for introducing an epoxy group include glycidyl (meth)acrylate, 3,4-epoxycyclohexylmethyl (meth)acrylate, and o- (or m- or p-)vinylbenzyl glycidyl ether.

In a case in which the polymer formed by polymerizing monomer components including a compound represented by Formula (ED) includes a monomer for introducing an epoxy group, the percentage content of the monomer is not particularly limited; however, the percentage content is preferably 5% to 70% by mass, and more preferably 10% to 60% by mass, with respect to the total amount of the monomer components.

Examples of the other copolymerizable monomer include (meth)acrylic acid esters such as methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, methyl 2-ethylhexyl (meth)acrylate, cyclohexyl (meth)acrylate, benzyl (meth)acrylate, and 2-hydroxyethyl (meth)acrylate; aromatic vinyl compounds such as styrene, vinyltoluene, and α-methylstyrene; N-substituted maleimides such as N-phenylmaleimide and N-cyclohexylmaleimide; butadiene or substituted butadiene compounds such as butadiene and isoprene; ethylene or substituted ethylene compounds such as ethylene, propylene, vinyl chloride, and acrylonitrile; and vinyl esters such as vinyl acetate. Among these, methyl (meth)acrylate, cyclohexyl (meth)acrylate, benzyl (meth)acrylate, and styrene are preferred from the viewpoint that these compounds have satisfactory transparency, and heat resistance is not easily impaired.

In a case in which the polymer formed by polymerizing monomer components including a compound represented by Formula (ED) includes another copolymerizable monomer, the percentage content of the monomer is not particularly limited; however, the percentage content is preferably 95% by mass or less, and more preferably 85% by mass or less.

The weight average molecular weight of the polymer formed by polymerizing monomer components including a compound represented by Formula (ED) is not particularly limited; however, from the viewpoints of the viscosity of the composition and the heat resistance of the coating film formed by the composition, the weight average molecular weight is preferably 2,000 to 200,000, more preferably 5,000 to 100,000, and even more preferably 5,000 to 20,000.

Furthermore, when the polymer formed by polymerizing monomer components including a compound represented by Formula (ED) has an acid group, the acid value is preferably 30 to 500 mg KOH/g, and more preferably 50 to 400 mg KOH/g.

The polymer formed by polymerizing monomer components including a compound represented by Formula (ED) can be easily obtained by polymerizing at least monomers including an ether dimer as an essential component. In this case, a cyclization reaction of the ether dimer proceeds simultaneously with polymerization, and a tetrahydropyran ring structure is formed.

The polymerization method applicable to the synthesis of the polymer formed by polymerizing monomer components including a compound represented by Formula (ED) is not particularly limited, and various polymerization methods that are conventionally known are employed. Particularly, it is preferable to follow a solution polymerization method. Specifically, a polymer formed by polymerizing monomer components including a compound represented by Formula (ED) can be synthesized according to, for example, the method for synthesizing polymer (a) described in JP2004-300204A.

Exemplary compounds (ED1) to (ED6) of the polymer formed by polymerizing monomer components including a compound represented by Formula (ED) are shown below, but the invention is not intended to be limited to these. The compositional ratios of the exemplary compounds shown below are on the basis of mol %.

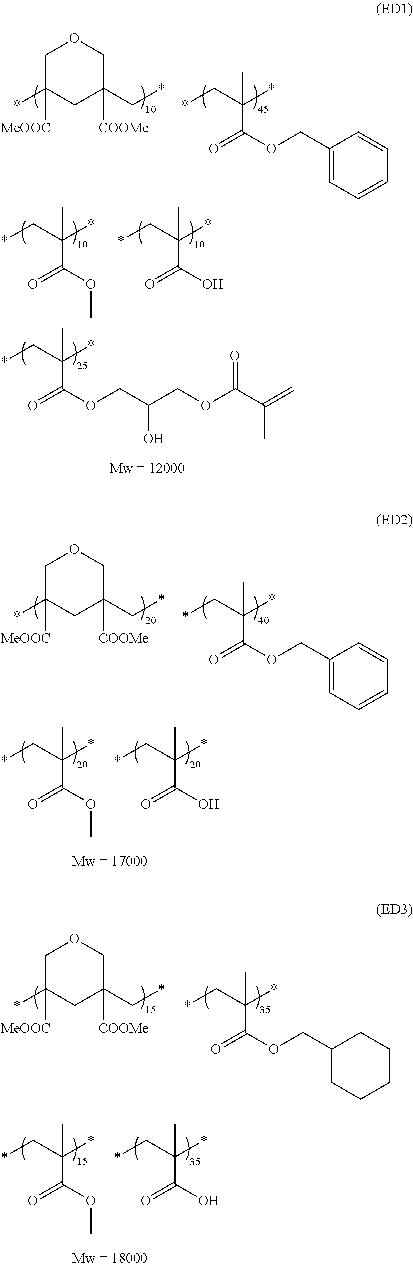

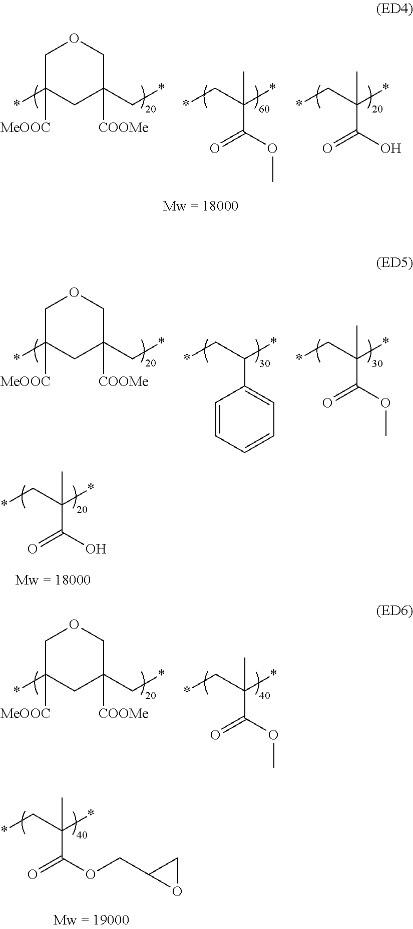

In this invention, particularly, a polymer produced by copolymerizing dimethyl-2,2′-[oxybis(methylene)]bis-2-propenoate (hereinafter, referred to as “DM”), benzyl methacrylate (hereinafter, referred to as “BzMA”), methyl methacrylate (hereinafter, referred to as “MMA”), methacrylic acid (hereinafter, referred to as “MAA”), and glycidyl methacrylate (hereinafter, referred to as “GMA”) is preferred. Particularly, it is preferable that the molar ratio of DM:BzMA:MMA:MAA:GMA is 5 to 15:40 to 50:5 to 15:5 to 15:20 to 30. It is preferable that 95% by mass or more of the components constituting the copolymer used in the invention is composed of these components. Furthermore, the weight average molecular weight of such a polymer is preferably 9,000 to 20,000.

It is preferable that the polymer used in the invention has a weight average molecular weight (value measured by a GPC method and calculated relative to polystyrene standards) of 1,000 to 2×10⁵, more preferably 2,000 to 1×10⁵, and even more preferably 5,000 to 5×10⁴.

The content of the polymer in the composition for forming a transparent resin layer is not particularly limited; however, from the viewpoint of having superior effects of the invention, the content is preferably 10% to 70% by mass, and more preferably 15% to 60% by mass, with respect to the total solid content of the composition for forming a transparent resin layer.

Furthermore, it is preferable that the composition of the invention includes the polymer formed by polymerizing monomer components including a compound represented by Formula (ED) at a proportion of 50% by mass or more, more preferably at a proportion of 80% by mass or more, and even more preferably at a proportion of 95% by mass or more, with respect to all the polymer components. It is particularly preferable for the composition of the invention that substantially all the polymers are polymers formed by polymerizing monomer components including a compound represented by Formula (ED).

The composition of the invention may include only one kind of the polymer, or may include two or more kinds of the polymer. When the composition includes two or more kinds of the polymer, it is preferable that the total amount is in the range described above.

(Other Components)

The composition for forming a transparent resin layer may include other components in addition to the polymerization initiator, polymerizable compound, and polymer described above. Examples thereof include an ultraviolet absorber, a solvent, an adhesion improving agent, a polymerization inhibitor, and a surfactant. The respective components will be described in detail below.

(Ultraviolet Absorber)

The composition for forming a transparent resin layer may include an ultraviolet absorber. Regarding the ultraviolet absorber, salicylate-based, benzophenone-based, benzotriazole-based, substituted acrylonitrile-based, and triazine-based ultraviolet absorbers can be used. Among them, benzotriazole-based and triazine-based ultraviolet absorbers are preferred.

Examples of a benzotriazole-based organic compound include 2-(5-methyl-2-hydroxyphenyl)benzotriazole, 2-(2-hydroxy-5-t-butylphenyl)-2H-benzotriazole, a mixture of octyl-3-[3-tert-butyl-4-hydroxy-5-(5-chloro-2H-benzotriazol-2-yl)phenyl]propionate and 2-ethylhexyl-3-[3-tert-butyl-4-hydroxy-5-(5-chloro-2H-benzotriazol-2-yl)phenyl]propionate, 2-[2-hydroxy-3,5-bis(α,α-dimethylbenzyl)phenyl]-2H-benzotriazole, 2-(3-t-butyl-5-methyl-2-hydroxyphenyl)-5-chlorobenzotriazole, 2-(3,5-di-t-amyl-2-hydroxyphenyl)benzotriazole, 2-(2′-hydroxy-5′-t-octylphenyl)benzotriazole, 5% of 2-methoxy-1-methylethyl acetate and 95% of benzenepropanoic acid, 3-(2H-benzotriazol-2-yl)-(1,1-dimethylethyl)-4-hydroxy, C7-9 side chain and linear alkyl ester compounds, 2-(2H-benzotriazol-2-yl)-4,6-bis(1-methyl-1-phenylethyl)phenol, and 2-(2H-benzotriazol-2-yl)-6-(1-methyl-1-phenylethyl)-4-(1,1,3,3-tetramethylbutyl)phenol.

More specific examples include “TINUVIN P”, “TINUVIN PS”, “TINUVIN 109”, “TINUVIN 234”, “TINUVIN 326”, “TINUVIN 328”, “TINUVIN 329”, “TINUVIN 384-2”, “TINUVIN 900”, “TINUVIN 928”, “TINUVIN 99-2”, and “TINUVIN 1130” manufactured by BASF SE.

From the viewpoints of colorability and resolution, a benzotriazole-based organic compound represented by the following Formula (10) is preferred (particularly, a compound represented by Formula (11) is preferred).

Meanwhile, in Formula (10), R₁ and R₂ each independently represent a hydrogen atom or an alkyl group having 1 to 20 carbon atoms which may contain a benzene ring; and X represents a hydrogen atom or a chlorine atom. However, it is more preferable that X represents a hydrogen atom.

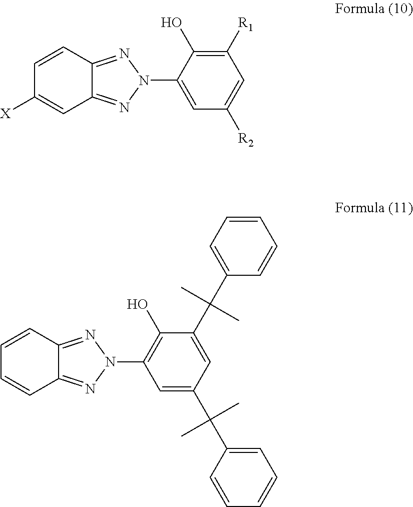

Examples of a triazine-based organic compound include 2-(4,6-di(2,4-xylyl)-1,3,5-triazin-2-yl)-5-octyloxyphenol, 2-[4,6-bis(2,4-dimethylphenyl)-1,3,5-triazin-2-yl]-5 [3-(dodecyloxy)-2-hydroxyprop oxy]p hen ol, a reaction product of 2-(2,4-dihydroxyphenyl)-4,6-bis(2,4-dimethylphenyl)-1,3,5-triazine and 2-ethylhexylglycidic acid ester, and 2,4-bis(2-hydroxy-4-butoxyphenyl)-6-(2,4-dibutoxyphenyl)-1,3,5-triazine.

More specific examples include “CHEMISORB 102” manufactured by Chemipro Kasei Kaisha, Ltd.; and “TINUVIN 400”, “TINUVIN 405”, “TINUVIN 460”, “TINUVIN 477-DW”, and “TINUVIN 479” manufactured by BASF SE.

Furthermore, examples of other ultraviolet absorbers include the diene-based compounds described in paragraphs <0022> to <0037> of JP2009-265642A (<0040> to <0061> of corresponding US2011/0039195A), the disclosure of which is incorporated herein. Examples of commercially available products include diethylaminophenylsulfonyl pentadienoate-based ultraviolet absorbers (manufactured by Fujifilm Finechemicals Co., Ltd., trade name: DPO).

According to the invention, various ultraviolet absorbers may be used singly or in combination of two or more kinds thereof.

The content of the ultraviolet absorber described above is not particularly limited; however, when the ultraviolet absorber is included in the composition for forming a transparent resin layer, the content is preferably 0 to 3.0% by mass with respect to the total solid content of the composition for forming a transparent resin layer.

<Solvent>

In general, the composition for forming a transparent resin layer of the invention can be formed using a solvent (usually, an organic solvent).

There are no particular limitations on the solvent as long as solubility of the various components and coatability of the composition for forming a transparent resin layer are satisfied; however, it is particularly preferable to select the solvent in consideration of the solubility of the ultraviolet absorber and the binder, coatability, and safety.

Preferred examples of the solvent include esters, for example, ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, and ethyl ethoxyacetate; 3-oxypropionic acid alkyl esters such as methyl 3-oxypropionate and ethyl 3-oxypropionate, for example, methyl 3-methoxypropionate, ethyl 3-methoxypropionate, methyl 3-ethoxypropionate, and ethyl 3-ethoxypropionate; 2-oxypropionic acid alkyl esters such as methyl 2-oxypropionate, ethyl 2-oxypropionate, and propyl 2-oxypropionate, for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate; methyl pyruvate, ethyl pyruvate, propyl pyruvate, methyl acetoacetate, ethyl acetoacetate, methyl 2-oxobutanoate, and ethyl 2-oxobutanoate; ethers, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate; ketones, for example, methyl ethyl ketone, cyclohexanone, 2-heptanone, and 3-heptanone; and aromatic hydrocarbons, for example, toluene and xylene.

As described above, these solvents may be used as mixtures of two or more kinds thereof from the viewpoints of the solubility of the ultraviolet absorber and the alkali-soluble resin, and improvement of the surface to be coated.

Particularly, a solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, 1-methoxy-2-propanol, and propylene glycol methyl ether acetate is suitably used.

The content of the solvent in the composition for forming a transparent resin layer is preferably 1% to 60% by mass, more preferably 1% to 50% by mass, even more preferably 5% to 50% by mass, particularly preferably 10% to 50% by mass, and most preferably 10% to 45% by mass, with respect to the total mass of the composition for forming a transparent resin layer from the viewpoint of coatability.

(Adhesion Improving Agent)

In order to enhance the adhesiveness of a transparent resin layer to a substrate, a so-called adhesion improving agent that is known in the art can be used.

Examples of the adhesion improving agent include benzimidazole, benzoxazole, benzothiazole, 2-mercaptobenzimidazole, 2-mercaptobenzoxazole, 2-mercaptobenzothiazole, 3-morpholinomethyl-1-phenyltriazole-2-thione, 3-morpholinomethyl-5-phenyloxadiazole-2-thione, 5-amino-3-morpholinomethylthiadiazole-2-thione, 2-mercapto-5-methylthiothiadiazole, triazole, tetrazole, benzotriazole, carboxybenzotriazole, amino group-containing benzotriazole, and a silane coupling agent. The adhesion improving agent is preferably a silane coupling agent.

The silane coupling agent is preferably a compound having an alkoxysilyl group as a hydrolyzable group capable of chemical bonding with an inorganic material. Furthermore, a silane coupling agent having a group which forms an interaction or bonding with an organic resin and exhibits affinity is preferred, and regarding such a group, a silane coupling agent having a (meth)acryloyl group, a phenyl group, a mercapto group, a glycidyl group, or an oxetanyl group is preferred. Among them, a silane coupling agent having a (meth)acryloyl group or a glycidyl group is preferred.

That is, the silane coupling agent used in the invention is preferably a compound having an alkoxysilyl group and a (meth)acryloyl group or an epoxy group, and specific examples thereof include a (meth)acryloyltrimethoxysilane compound and a glycidyltrimethoxysilane compound having the following structures.

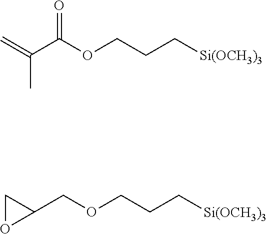

Furthermore, regarding the silane coupling agent, a silane compound having at least two functional groups having different reactivity in one molecule is also preferred, and particularly, a silane compound having an amino group and an alkoxy group as functional groups is preferred. Examples of such a silane coupling agent include N-2-(aminoethyl)-3-aminopropylmethyldimethoxysilane, N-β-aminoethyl-γ-aminopropylmethyldimethoxysilane (trade name: KBM-602 manufactured by Shin-Etsu Chemical Co., Ltd.), N-β-aminoethyl-γ-aminopropyltrimethoxysilane (trade name: KBM-603 manufactured by Shin-Etsu Chemical Co., Ltd.), N-β-aminoethyl-γ-aminopropyltriethoxysilane (trade name: KBE-602 manufactured by Shin-Etsu Chemical Co., Ltd.), γ-aminopropyltrimethoxysilane (trade name: KBM-903 manufactured by Shin-Etsu Chemical Co., Ltd.), γ-aminopropyltriethoxysilane (trade name: KBE-903 manufactured by Shin-Etsu Chemical Co., Ltd.), and 3-methacryloxypropyltrimethoxysilane (trade name: KBM-503 manufactured by Shin-Etsu Chemical Co., Ltd.).

The content of the adhesion improving agent is preferably 0.001% to 20% by mass, more preferably 0.001% to 10% by mass, and particularly preferably 0.001% to 5% by mass, with respect to all the components excluding the solvent of the composition for forming a transparent resin layer.

(Polymerization Inhibitor)

In regard to the composition for forming a transparent resin layer, it is preferable to add a small amount of a polymerization inhibitor in order to inhibit unnecessary thermal polymerization of the polymerizable compound during the production or storage of the composition.

Examples of the polymerization inhibitor that can be used in the invention include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxyamine cerous salt.

The content of the polymerization inhibitor is preferably 0.001% to 5% by mass, and more preferably 0.01% to 3% by mass, with respect to the total mass of the composition for forming a transparent resin layer.

(Surfactant)

In the composition for forming a transparent resin layer, various surfactants may be incorporated from the viewpoint of further enhancing coatability. Regarding the surfactant, various surfactants such as a fluorine-based surfactant, a nonionic surfactant, a cationic surfactant, an anionic surfactant, and a silicone-based surfactant can be used.

Particularly, when the composition for forming a transparent resin layer contains a fluorine-based surfactant, liquid characteristics obtainable when the composition is prepared as a coating liquid (particularly, fluidity) are further enhanced. Therefore, uniformity after coating and liquid saving properties can be further improved.

That is, in a case in which a film is formed using a coating liquid to which a composition containing a fluorine-based surfactant is applied, when the interfacial tension between the surface to be coated and the coating liquid is decreased, wettability of the surface to be coated is improved, and coatability onto the surface to be coated is enhanced. For this reason, it is effective from the viewpoint that even in a case in which a thin film having a thickness of about several micrometers (μm) is formed with a small amount of liquid, the formation of a film having a uniform thickness with less thickness unevenness can be performed more appropriately.

The percentage of fluorine content in the fluorine-based surfactant is suitably 3% to 40% by mass, more preferably 5% to 30% by mass, and particularly preferably 7% to 25% by mass. A fluorine-based surfactant having a percentage of fluorine content in this range is effective from the viewpoints of uniformity of the thickness of the coating liquid, and liquid saving properties, and the solubility of the fluorine-based surfactant in the composition is also satisfactory.

Examples of the fluorine-based surfactant include MEGAFAC F171, MEGAFAC F172, MEGAFAC F173, MEGAFAC F176, MEGAFAC F177, MEGAFAC F141, MEGAFAC F142, MEGAFAC F143, MEGAFAC F144, MEGAFAC R30, MEGAFAC F437, MEGAFAC F475, MEGAFAC F479, MEGAFAC F482, MEGAFAC F554, MEGAFAC F780, and MEGAFAC F781 (all manufactured by DIC Corp.); FLUORAD FC430, FLUORAD FC431, and FLUORAD FC171 (all manufactured by Sumitomo 3M, Ltd.); SURFLON S-382, SURFLON SC-101, SURFLON SC-103, SURFLON SC-104, SURFLON SC-105, SURFLON SC-1068, SURFLON SC-381, SURFLON SC-383, SURFLON S393, and SURFLON KH-40 (manufactured by Asahi Glass Co., Ltd.); and PF636, PF656, PF6320, PF6520, and PF7002 (manufactured by Omnova Solutions, Inc.).

Specific examples of the nonionic surfactant include glycerol, trimethylolpropane, trimethylolethane and ethoxylates and propoxylates thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid esters (PLURONIC L10, L31, L61, L62, 10R5, 17R2, and 25R2 and TETRONIC 304, 701, 704, 901, 904, and 150R1 manufactured by BASF SE; and SOLSPERSE 20000 (manufactured by Lubrizol Japan, Ltd.).

Specific examples of the cationic surfactant include a phthalocyanine derivative (trade name: EFKA-745, manufactured by Morishita Kagaku Sangyo Corp.), an organosiloxane polymer KP341 (manufactured by Shin-Etsu Chemical Co., Ltd.), (meth)acrylic acid-based (co)polymer POLYFLOW No. 75, No. 90, and No. 95 (manufactured by Kyoeisha Co., Ltd.), and W001 (manufactured by Yusho Co., Ltd.).

Specific examples of the nonionic surfactant include W004, W005, and W017 (manufactured by Yusho Co., Ltd.).

Examples of the silicone-based surfactant include “TORAY SILICONE DC3PA”, “TORAY SILICONE SH7PA”, “TORAY SILICONE DC11PA”, “TORAY SILICONE SH21PA”, “TORAY SILICONE SH28PA”, “TORAY SILICONE SH29PA”, “TORAY SILICONE SH30PA”, and “TORAY SILICONE SH8400” manufactured by Dow Corning Toray Co., Ltd.; “TSF-4440”, “TSF-4300”, “TSF-4445”, “TSF-4460”, and “TSF-4452” manufactured by Momentive Performance Materials, Inc.; “KP341”, “KF6001”, and “KF6002” manufactured by Shin-Etsu Silicones, Inc.; and “BYK307”, “BYK323”, and “BYK330” manufactured by BYK Chemie GmbH.

The surfactants may be used singly or in combination of two or more kinds thereof.

The content of the surfactant is preferably 0.001% to 5.0% by mass, and more preferably 0.001% to 3.0% by mass, with respect to the total mass of the composition for forming a transparent resin layer.

(Others)

The composition for forming a transparent resin layer of the invention can include, if necessary, various additives, for example, a polymerization inhibitor, a surfactant, a filler, a polymer compound other than those described above, a chain transfer agent (paragraphs <0216> to <0220> of JP2012-150468A), an oxidation inhibitor, and an aggregation inhibitor.

Specific examples of these additives include fillers such as glass and alumina; oxidation inhibitors such as 2,2-thiobis(4-methyl-6-t-butylphenol) and 2,6-di-t-butylphenol; and aggregation inhibitors such as poly(sodium acrylate).

Furthermore, in the case of promoting alkali solubility at a non-ultraviolet-irradiated part of the composition for forming a transparent resin layer and further promoting an increase in developability, the composition for forming a transparent resin layer of the invention may include an organic carboxylic acid, and preferably a low molecular weight organic carboxylic acid having a molecular weight of 1000 or less.

Specific examples of the organic carboxylic acid include aliphatic monocarboxylic acids such as formic acid, acetic acid, propionic acid, butyric acid, valeric acid, pivalic acid, caproic acid, diethylacetic acid, enanthic acid, and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acids such as tricarballylic acid, aconitic acid, and camphoronic acid; aromatic monocarboxylic acids such as benzoic acid, toluic acid, cumic acid, hemellitic acid, and mesitylenic acid; aromatic polycarboxylic acids such as phthalic acid, isophthalic acid, terephthalic acid, trimellitic acid, trimesic acid, mellophanic acid, and pyromellitic acid; and other carboxylic acids such as phenylacetic acid, hydratropic acid, hydrocinnamic acid, mandelic acid, phenylsuccinic acid, atropic acid, cinnamic acid, methyl cinnamate, benzyl cinnamate, cinnamylidene acetic acid, coumaric acid, and umbellic acid.

(Filter Filtration)

It is preferable that the composition for forming a transparent resin layer is filtered through a filter for the purpose of eliminating foreign materials or reducing defects. Any filter that has been conventionally used for filtration applications can be used without any particular limitations.

Regarding the filter used for the filter filtration, any filter that has been conventionally used for filtration applications and the like can be used without any particular limitations.

Examples of the material of the filter include fluororesins such as PTFE (polytetrafluoroethylene); polyamide-based resins such as nylon-6 and nylon 6,6; and polyolefin resins (including high density and ultrahigh molecular weight resins) such as polyethylene and polypropylene (PP). Among these materials, polypropylene (including high density polypropylene) is preferred.

The pore diameter of the filter is not particularly limited; however, for example, the pore diameter is about 0.01 μm to 20.0 μm, preferably about 0.1 μm to 15.0 μm, and more preferably about 1 μm to 10.0 μm.

When the pore diameter of the filter is adjusted to the range described above, fine particles can be removed more effectively, and turbidity can be further decreased.

Here, regarding the pore diameter of the filter, reference can be made to nominal values provided by filter manufacturers. Regarding commercially available filters, a filter can be selected from various filters supplied by, for example, Nihon Pall, Ltd., Advantec Toyo Kaisha, Ltd., Nihon Entegris K.K. (formerly Nihon Mykrolis K.K.), and Kitz Microfilter Corp.

For the filter filtration, two or more kinds of filter may be used in combination.

For example, first, filtration is performed using a first filter, and then filtration can be performed using a second filter having a pore diameter different from that of the first filter.

In that case, filtering with the first filter and filtering with the second filter may be carried out only once, or may be carried out two or more times.

Regarding the second filter, a filter formed from the same material as that of the first filter can be used.

<Method for Producing Transparent Resin Layer>

A transparent resin layer in which coloration does not easily occur even at the time of heat treatment can be formed from the composition for forming a transparent resin layer described above.

The method for producing a transparent resin layer is not particularly limited, and any known method can be employed. More specifically, there is available a method in which the composition for forming a transparent resin layer is applied on a predetermined substrate, thereby a coating film is formed, the coating film is cured by subjecting the coating film to a curing treatment such as a heating treatment and/or a light irradiation treatment, the coating film is post-baked as necessary, and then a transparent resin layer (cured film) is obtained.

Furthermore, when the transparent resin layer is formed in a pattern form, a method including the following steps is preferred.

(1) A step of applying a composition for forming a transparent resin layer on a substrate,

(2) a step of exposing the applied composition for forming a transparent resin layer,

(3) a step of developing the exposed composition for forming a transparent resin layer, and

(4) a post-baking step of thermally curing the composition for forming a transparent resin layer after development.

The procedure of the various steps are described in detail below.

(Step (1))

Step (1) is a step of applying a composition for forming a transparent resin layer on a substrate. More specifically, Step (1) is a step of forming a layer of the composition for forming a transparent resin layer on a substrate.

The kind of the substrate to be used is not particularly limited, and it is preferable to use a glass wafer, a silicon wafer, or a silicon wafer provided with another layer.

Furthermore, regarding the method for applying the composition for forming a transparent resin layer, coating is preferred, and for example, various methods such as a spray method, a roll coating method, and a rotary coating method can be used.

In order to sufficiently dry the applied composition for forming a transparent resin layer, it is preferable to perform prebaking before the subsequent step. The method for prebaking is not particularly limited as long as the prebaking is prevented from causing thermal curing of the composition and adversely affecting patterning, and a method of performing prebaking in a heating apparatus such as a hot plate or an oven at a predetermined temperature, for example, at 80° C. to 120° C., for a predetermined time, for example, for 1 to 3 minutes on a hot plate and for 1 to 30 minutes in an oven, may be used.

(Step (2))

Step (2) is a step of exposing the applied composition for forming a transparent resin layer. In an exposed region, polymerization of the polymerizable compound proceeds, and an insoluble cured film is obtained.

The method for exposure is not particularly limited, and for example, a method of patternwise exposing the composition by irradiating light (preferably, ultraviolet radiation) to the composition through a photomask may be used.

The ultraviolet radiation used at least for the exposure is preferably at least one of g-ray, h-ray, and i-ray, and i-ray is more preferred.

Regarding the exposure machine, for example, a stepper can be suitably used.

(Step (3))

Step (3) is a step of developing the exposed composition for forming a transparent resin layer. More specifically, Step (3) is a step of removing any unexposed region that has not been exposed.

The developing method is not particularly limited; however, for example, developing may be performed by subjecting the exposed composition for forming a transparent resin layer to a developing treatment with an alkaline developing liquid.

Examples of the alkaline developing liquid that can be used include aqueous solutions of inorganic alkalis such as sodium hydroxide, potassium hydroxide, sodium carbonate, sodium silicate, sodium metasilicate, and ammonia; primary amines such as ethylamine and n-propylamine; secondary amines such as diethylamine and di-n-propylamine; tertiary amines such as trimethylamine, methyldiethylamine, dimethylethylamine, and triethylamine; alkanolamines such as dimethylethanolamine, methyldiethanolamine, and triethanolamine; cyclic tertiary amines such as pyrrole, piperidine, N-methylpiperidine, N-methylpyrrolidine, 1,8-diazabicyclo[5.4.0]-7-undecene, and 1,5-diazabicyclo[4.3.0]-5-nonene; aromatic tertiary amines such as pyridine, collidine, lutidine, and quinoline; and quaternary ammonium salts such as tetramethylammonium hydroxide and tetraethylammonium hydroxide.

Furthermore, a water-soluble solvent such as methanol or ethanol and/or a surfactant can be added in an appropriate amount to the alkaline developing liquid.

The developing method may be any of a liquid filling method, a dipping method, a showering method, and the like, and the developing time is usually 30 to 180 seconds.

After the alkali development, for example, washing under flowing water is carried out for 30 to 90 seconds, and the composition is dried with compressed air or compressed nitrogen. Thereby, a pattern is formed.

(Step (4))

Step (4) is a post-baking step of thermally curing the composition for forming a transparent resin layer after development.

The method for post-baking is not particularly limited, and a method of performing post-baking in a heating apparatus such as a hot plate or an oven, at a predetermined temperature, for example, 130° C. to 250° C., and at a predetermined time, for example, for 5 to 30 minutes on a hot plate and for 30 to 180 minutes in an oven, may be used.

The thickness of the transparent resin layer is not particularly limited; however, when the composition for forming a transparent resin layer of the invention is used, a thick transparent resin layer can be formed. More specifically, a transparent resin layer having a thickness of 2 μm or more, preferably 4 μm or more, and more preferably 10 μm or more, can be formed. When it is considered that the transparent resin layer is used in a solid imaging element or the like, the thickness of the transparent resin layer is preferably 2 to 50 μm, more preferably 4 to 50 μm, and even more preferably 10 to 50 μm.

Furthermore, the transparent resin layer may be composed of plural layers, and a laminate of 2 layers, 3 layers or 4 layers of transparent resin layers (preferably having a thickness of 2 to 25 μm, more preferably 4 to 20 μm, and particularly preferably 8 to 20 μm) may also be used.

When the composition for forming a transparent resin layer of the invention is used, a transparent resin layer having an excellent surface state and a uniform film thickness can be formed, regardless of being a thick film such as described above or being a multilayer film.

When a transparent resin layer is formed using the composition for forming a transparent resin layer of the invention, a transparent resin layer having a desired film thickness may be formed by applying the composition several times.

Specifically, the composition is applied and dried, and the position intended to be patterned is exposed at this film thickness. This pattern is designated as a first pattern. Then, the composition is further applied and dried on this coated substrate, and the position intended to be patterned (second pattern) is exposed at this film thickness. Similarly, the processes of application, drying, and exposure are repeated so that a third pattern and a fourth pattern can be formed. Lastly, this is developed and post-baked, and thereby a pattern having plural film thicknesses can be formed on the same substrate.

For example, when the coated film thickness is set to 10 μm, and three kinds of pattern are formed by repeating the above-described method three times, a first pattern having a film thickness of 10 μm, a second pattern having a film thickness of 20 μm, and a third pattern having a film thickness of 30 μm can be formed on the same substrate. The coated film thickness may be adjusted to 6 μm by applying the composition three times to a thickness of 2 μm each time, or may be adjusted to 15 μm by applying the composition three times to a thickness of 5 μm each time.

The transparent resin layer of the invention can be used in a liquid crystal display apparatus, a solid imaging element (for example, a CMOS sensor, or an organic CMOS sensor), and an organic EL element, and the transparent resin layer is particularly suitable for solid imaging applications.

Furthermore, the composition for forming a transparent resin layer of the invention can be suitably used in the production process of an integrated optical system described in JP2007-524243A described above (<0073> to <0118> of corresponding US2007/0009223A). Meanwhile, the disclosure of JP2007-524243A is incorporated in the present specification.

More specifically, there is available a method for producing an integrated optical system, the method including a step of supplying a wafer having active optical components, in which step various active optical components have optically active surfaces; and a step of providing an optical structure assigned to an active optical component that functions so as to affect the electromagnetic radiation emitted by the optical active surface and/or the electromagnetic radiation that affects the optical active surface, characterized in that the optical structure is provided by adding a protective layer to a wafer and partially covering the surface of the wafer with the protective layer; by disposing a transparent resin layer formed from the composition for forming a transparent resin layer in at least some of the active optical components; by replicating the optical structure onto the surface of a transparent substance by an aligning method by means of a replication tool, and thereby bringing the replication tool into contact with the protective layer or projections thereof in a replication process; and by eliminating the protective layer. This method for producing an integrated optical system further includes a step of separating a semiconductor wafer having an optical structure into sections each including at least one active optical component and at least one optical structure.

Meanwhile, it is preferable that the transparent resin layer includes at least two layers, and a first layer of the two layers that cover the active optical component is thicker than the outermost layer of the at least two layers.

Furthermore, it is preferable that the replication tool includes a groove shape that forms a cavity when the replication tool is placed on a flat surface, the structure inside the replication tool has a groove shape, the composition for forming a transparent resin layer used for the formation of the transparent resin layer is locally disposed at a place where the optical structure should exist, and the groove shape prevents overflow of the composition for forming a transparent resin layer to the outside of a limited region during the replication process.

Furthermore, it is preferable that the composition for forming a transparent resin layer is disposed in a groove shape on the replication tool, and this is attached to the wafer before and after curing.

It is also preferable that the composition for forming a transparent resin layer is disposed in grooves formed by recesses of the protective layer, or is disposed over a wide area on the wafer including a protective layer.

The integrated optical system described above is a system including active and passive optical components, elements and system components, and an example is a CMOS camera module.

Furthermore, an active optical component is an optical sensing or light emitting device, and examples thereof include a detector, an image sensor, a LED, a VCSEL, a laser, and an OLED. The term “optically active” means functioning so as to interact with electromagnetic radiation, or emitting electromagnetic radiation.

Furthermore, a passive optical component means a refractive or diffractive optical component, and includes optical systems (optical elements, and a group of mechanical forms such as an aperture stop, a screen, and a holder). This term is not limited to micro-optical elements, and is also used for “classical” optical elements such as lenses, prisms, and mirrors.

Furthermore, a wafer (optoelectronic wafer) means a semiconductor wafer including active optical components/an array of active optical components having regions.

Furthermore, the meanings of “light”, “replication”, “micro-optical instrument”, “optical wafer”, and “wafer scale” are the same as the meanings described in paragraphs <0006> to <0013> of JP2007-524243A (<0010> to <0018> of corresponding US2007/0009223A), the disclosure of which is incorporated herein.

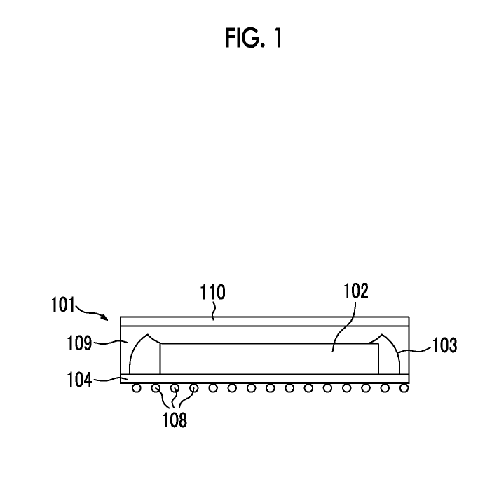

Furthermore, an embodiment of the application of the transparent resin layer of the invention to an integrated optical system will be described with reference to FIG. 1.

FIG. 1 is based on the idea that a semiconductor component/device will be encapsulated by a two-layer system. The material in the volume under the outermost protective layer needs to have certain required characteristics such as compatibility with environmental tests, optoelectronic production processes (for example, IR reflow), and optical transparency and quality. In principle, a first layer provides a certain distance (for example, thick enough to cover and protective bonding wires, or to dispose the optical instrument at a correct z-position), and has a function of securing mechanical parameters (in this case, the first layer has a low E module in order to reduce mechanical stress). A material class that has been proved to be suitable for constituting the “volume” layer is a material having low elastic module and high optical transparency. This is because the large volume of this material is exposed to environmental conditions including high and rapid temperature changes. In order to prevent bending of a thick layer on a thin or flexible substrate, there are two options:

(i) A material having the same coefficient of thermal expansion (CTE) as that of the substrate and the outermost protective layer is used. This is generally impossible for plastics (top surface) and semiconductors (bottom).

(ii) A material having a very low E module (that is, low expansion) is used.

The transparent resin layer of the invention is an example of such a material. The transparent resin layer of the invention also accomplishes new requirements such as high optical transparency, high resistance to the environmental test conditions, and the like (separately from low E-module).

FIG. 1 illustrates encapsulation of a die 102 that is in contact with a binder 103 in an optoelectronic chip 101. The die 102 is disposed on an interposer 104 which includes an array of solder bumps 108 (ball grid array, BGA) on the posterior side in order to be brought into contact with an interconnection board or a printed board (not shown in the diagram). At least one of a first layer 109 and a second layer 110 is the transparent resin layer of the invention. Meanwhile, when the first layer 109 or the second layer 110 is not the transparent resin layer of the invention, a polydimethylsiloxane (PDMS) layer, an epoxy layer or the like is used.

Furthermore, the composition for forming a transparent resin layer of the invention can also be suitably used in a method for producing an optical device.

More specifically, it is a method for producing an optical device, the method including a step of providing a first optically functional wafer and a second optically functional wafer; a step of applying a composition for forming a transparent resin layer on a first side of the first wafer, with the composition for forming a transparent resin layer being a curable and deformable material; a step of applying the second wafer by an aligning method, and thereby bringing a first side of the second wafer into contact with the composition for forming a transparent resin layer; a step of curing the composition for forming a transparent resin layer, with the space between the first wafer and the second wafer being controlled during the curing of the composition for forming a transparent resin layer; and a step of dividing the assembly including the first wafer, the second wafer, and the transparent resin layer consequently obtained, into plural devices.

Meanwhile, it is preferable that the composition for forming a transparent resin layer is applied by a printing process.

Furthermore, it is preferable that the composition for forming a transparent resin layer is applied using a replication tool for a composition for forming a transparent resin layer.

As discussed above, a transparent resin layer formed by curing the composition for forming a transparent resin layer can be suitably used in optoelectronics devices.

### EXAMPLES

Hereinafter, the invention will be described more specifically by way of Examples; however, the invention is not intended to be limited to the following Examples as long as the main gist is maintained. Meanwhile, unless particularly stated otherwise, the unit “parts” is on a mass basis.

### Synthesis Example 1

### Polymer B-1

A solution having the following composition was prepared in a vessel for dropwise addition of monomers.

| | |
|---|---|
| Dimethyl-2,2′-[oxybis(methylene)]bis-2-propenoate | 13 parts |
| (hereinafter, referred to as “DM”) | |
| Benzyl methacrylate (hereinafter, referred to as “BzMA”) | 63 parts |
| Methyl methacrylate (hereinafter, referred to as “MMA”) | 15 parts |
| Methacrylic acid (hereinafter, referred to as “MAA”) | 38 parts |
| t-Butyl peroxy-2-ethylhexanoate | 2 parts |
| Diethylene glycol dimethyl ether | 32 parts |

A solution having the following composition was prepared in a vessel for dropwise addition of a chain transfer agent.

| | |
|---|---|
| n-Dodecanethiol | 6 parts |
| Diethylene glycol dimethyl ether | 20 parts |

188 parts of diethylene glycol dimethyl ether was introduced into a reaction vessel (separable flask equipped with a condenser), the vessel was purged with nitrogen, and then the vessel was heated to increase the temperature of the reaction vessel to 90° C.

After it was confirmed that the temperature was stable, dropping from the vessel for dropwise addition of monomers and the vessel for dropping a chain transfer agent was initiated, and dropping of the monomers and the chain transfer agent was completed after 140 minutes while the temperature was maintained at 90° C.

The temperature was further increased to rise the temperature of the reaction vessel to 110° C. after 60 minutes of completion of the dropping, and the temperature was maintained at 110° C. for 180 minutes. Thereafter, the reaction vessel was purged with air.

Next, compounds of the following composition were introduced into the reaction vessel, and the mixture was allowed to react for 9 hours while maintained at the temperature of 110° C.

| | |
|---|---|
| Glycidyl methacrylate (hereinafter, referred to as “GMA”) | 41 parts |
| 2,2′-Methylenebis(4-methyl-6-t-butylphenol) | 0.2 parts |
| Triethylamine | 0.4 parts |

After completion of the reaction, 27 parts of diethylene glycol dimethyl ether was added thereto, the mixture was cooled to room temperature, and thus a polymer B-1 was obtained.

### Synthesis Example 2

### Polymer B-2

A solution having the following composition was prepared in a vessel for dropping monomers.

| | |
|---|---|
| DM | 22 parts |
| BzMA | 70 parts |
| MMA | 10 parts |
| MAA | 34 parts |
| t-Butyl peroxy-2-ethylhexanoate | 2 parts |
| Diethylene glycol dimethyl ether | 34 parts |

A solution having the following composition was prepared in a vessel for dropping a chain transfer agent.

| | |
|---|---|
| n-Dodecanethiol | 6 parts |
| Diethylene glycol dimethyl ether | 20 parts |

188 parts of diethylene glycol dimethyl ether was introduced into a reaction vessel (condenser-attached separable flask), the reaction vessel was purged with nitrogen, and then the vessel was heated to increase the temperature of the reaction vessel to 90° C.

After it was confirmed that the temperature was stable, dropping from the vessel for dropping monomers and the vessel for dropping a chain transfer agent was initiated, and dropping of the monomers and the chain transfer agent was completed after 140 minutes while the temperature was maintained at 90° C.

The temperature was further increased to rise the temperature of the reaction vessel to 110° C. after 60 minutes of completion of the dropping, and the temperature was maintained at 110° C. for 180 minutes. Thereafter, the reaction vessel was purged with air.

Next, compounds of the following composition were introduced into the reaction vessel, and the mixture was allowed to react for 9 hours while maintained at the temperature of 110° C.

| | |
|---|---|
| GMA | 43 parts |
| 2,2′-Methylenebis(4-methyl-6-t-butylphenol) | 0.2 parts |
| Triethylamine | 0.4 parts |

After completion of the reaction, 39 parts of diethylene glycol dimethyl ether was added thereto, the mixture was cooled to room temperature, and thus a polymer B-2 was obtained.

Solid contents of the polymer B-1 and the polymer B-2 obtained from the Synthesis Examples described above were measured. Also, the components derived from the various raw material monomers were analyzed using ¹H-NMR. Furthermore, the weight average molecular weights were measured by GPC. The evaluation results are presented in the following Table 1.

TABLE 1

| | Sold | | | | | | |
|---|---|---|---|---|---|---|---|
| | content | | | | | | Weight |
| | concen- | Raw material monomer- | | | | | average |
| | tration | derived component ratio (mol %) | | | | | molecular |
| | (mass %) | DM | BzMA | MMA | MAA | GMA | weight |
| Polymer | 40 | 5 | 35 | 15 | 15 | 30 | 12000 |
| B-1 | | | | | | | |
| Polymer | 40 | 10 | 40 | 10 | 10 | 30 | 11000 |
| B-2 | | | | | | | |

### Example 1

Various components were mixed to obtain the following composition, and thus a composition for forming a transparent resin layer 1 was obtained.

| | |
|---|---|
| Polymer B-1 a 40% propylene glycol-1-monomethyl | 59.55 parts by mass |
| ether-2-acetate (hereinafter, also referred | |
| to as PGMEA) solution | |
| Polymerizable compound (A-1) | 35.73 parts by mass |
| Polymerization initiators (IRGACURE 184) | 1.286 parts by mass |
| (Darocur 1173) | 1.715 parts by mass |
| (Darocur TPO) | 0.429 parts by mass |
| Silane coupling agent ((N-2-(aminoethyl)-3- | 0.31 parts by mass |
| aminopropylmethyldimethoxysilane)) a 1% | |
| cyclohexanone solution | |
| Polymerization inhibitor (p-methoxyphenol) | 0.02 parts by mass |
| Surfactant (MEGAFAC F-781F manufactured | 0.873 parts by mass |
| by DIC Corp.) a 0.2% propylene | |
| glycol-1-monomethyl ether-2-acetate solution | |
| Propylene glycol-1-monomethyl ether-2-acetate | 0.08 parts by mass |

Meanwhile, the polymerizable compound (A-1) is ARONIX M-510 manufactured by Toagosei Co., Ltd. The polymerizable compound (A-1) is a mixture of two compounds having structures as shown below, and the acid value thereof is 100 mg KOH/g.

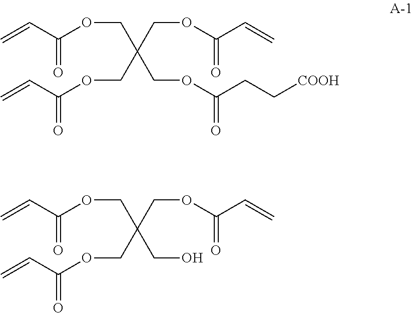 [SMILES: C=CC(=O)OCC(COC(=O)C=C)(COC(=O)C=C)COC(=O)CCC(=O)O ; C=CC(=O)OCC(CO)(COC(=O)C=C)COC(=O)C=C]

[Production of Transparent Resin Layer]

The composition for forming a transparent resin layer 1 obtained as described above was applied on a soda glass plate (75 mm×75 mm square, thickness 1.1 mm) by a spin coating method, and thereafter, the glass plate was heated for 2 minutes at 100° C. on a hot plate. Thus, a coating film was obtained. This coating film was exposed at 400 mJ/cm² using an ultrahigh pressure mercury lamp “USH-500BY” manufactured by Ushio, Inc. Furthermore, the glass plate was heated on a hot plate at 200° C. for 5 minutes, and thus a transparent cured layer (transparent resin layer) (final film thickness: 25 μm) was obtained.

Meanwhile, as will be described below, other cured layers were separately produced by a similar method so as to obtain a final thickness of 30 μm or 33 μm.

[Spectrometry (Transmissivity)]

The transparent resin layer (final film thickness: 25 μm) produced as described above was heated on a hot plate at 265° C. for 5 minutes, and the spectroscopic characteristics (transmissivity) of the transparent resin layer after heating were measured at a wavelength of 400 nm with a “MCPD-3000” manufactured by Otsuka Electronics Co., Ltd.

A transparent resin layer produced separately (final film thickness: 25 μm) was heated on a hot plate at 200° C. for 60 minutes, and the spectroscopic characteristics (transmissivity) of the transparent resin layer after heating was measured at a wavelength of 400 nm with a “MCPD-3000” manufactured by Otsuka Electronics Co., Ltd.

[Pattern Forming Properties]

The composition for forming a transparent resin layer 1 was applied on a soda glass plate (100 mm×100 mm square, thickness 0.7 mm) by a spin coating method, and subsequently, the soda glass plate was heated for 2 minutes at 100° C. on a hot plate. Thus, a coating film was obtained. This coating film was exposed at 400 mJ/cm² using an ultrahigh pressure mercury lamp “USH-500BY” manufactured by Ushio, Inc., through a mask having a number of circular patterns each having a diameter of 50 μm.

This was subjected to puddle development for 60 seconds at room temperature using an alkaline developing liquid (FHD-5) (manufactured by Fujifilm Electronic Materials, Inc.), and then the substrate was rinsed with pure water for 60 seconds. Subsequently, the substrate was dried by high speed rotation, and thus patterns were formed. The substrate was evaluated according to the following criteria.

“A”: Patterns have been formed sharply without any residue.

“B”: Although there is residue, the pattern shapes are not poor.

“C”: There is a large amount of residue, and the pattern shapes are poor.

### Examples 1 to 9 and Comparative Examples 1 to 3

Transparent resin layers were formed according to the same procedure as that used in Example 1, except that the kinds of the components used (polymerization initiators, polymers, and polymerizable compounds) were changed as indicated in the following Table 2, and various evaluations were performed. The results are summarized in Table 2.

Meanwhile, in Example 2, IRGACURE 184 (3.001 parts by mass) and Darocur TPO (0.429 parts by mass) were used as polymerization initiators.

In Example 3, IRGACURE 184 (3.001 parts by mass) and IRGACURE 819 (0.429 parts by mass) were used as polymerization initiators.

In Example 4, IRGACURE 184 (3.430 parts by mass) was used as a polymerization initiator.

In Example 5, Darocur 1173 (3.430 parts by mass) was used as a polymerization initiator.

In Example 6, a transparent resin layer was formed according to the same procedure as that used in Example 1 using a transparent photosensitive resin composition having the same composition as that of Example 2, except that a polymerizable compound (A-4) represented by the following formulas was used instead of the polymerizable compound (A-1), and various evaluations were performed.

The polymerizable compound (A-4) is TO-2349 manufactured by Toagosei Co., Ltd. The polymerizable compound (A-4) is a mixture of three compounds having structures as shown below, and the acid value thereof is 68 mg KOH/g.

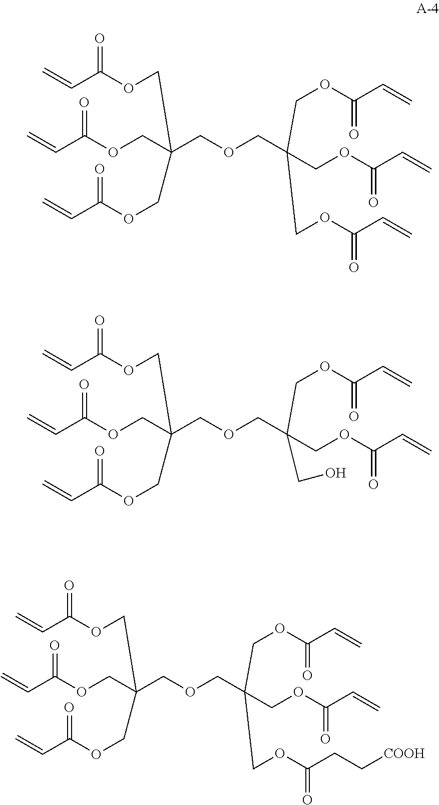

In Example 7, a transparent resin layer was formed according to the same procedure as that used in Example 1, except that a composition for forming a transparent resin layer obtained by mixing various components to obtain the following composition was used, and various evaluations were performed.

| | |
|---|---|
| Polymer B-1 (40% PGMEA solution) | 42.60 parts by mass |
| Polymerizable compound (A-4) | 51.12 parts by mass |
| Polymerization initiators (IRGACURE 184) | 4.294 parts by mass |
| (Darocur TPO) | 0.613 parts by mass |
| Silane coupling agent ((N-2-(aminoethyl)-3- | 0.37 parts by mass |
| aminopropylmethyldimethoxysilane)) a 1% | |
| cyclohexanone solution | |
| Polymerization inhibitor (p-methoxyphenol) | 0.03 parts by mass |
| Surfactant (MEGAFAC F-781F manufactured by | 0.87 parts by mass |
| DIC Corp.) a 0.2% propylene glycol-1-monomethyl | |
| ether-2-acetate solution | |
| PGMEA | 0.11 parts by mass |

In Example 8, Darocur TPO (3.430 parts by mass) was used as a polymerization initiator.

In Example 9, IRAGACURE 819 (3.430 parts by mass) was used as a polymerization initiator.

In Comparative Example 1, IRGACURE OXE 01 (3.430 parts by mass) was used.

In Comparative Example 2, IRGACURE OXE 01 (3.430 parts by mass) was used.

In Comparative Example 3, C-1 that will be described below (3.430 parts by mass) was used.

In Table 2, in regard to the term “25 μm film thickness”, a case in which a transparent resin layer having a thickness of 25 μm could be formed is indicated as “OK”; and a case in which a transparent resin layer having a thickness of 25 μm could not be formed is indicated as “NG”. In Table 2, in regard to the term “30 μm film thickness”, a case in which a transparent resin layer having a thickness of 30 μm could be formed is indicated as “OK”; and a case in which a transparent resin layer having a thickness of 30 μm could not be formed is indicated as “NG”. Furthermore, in Table 2, in regard to the term “33 μm film thickness”, a case in which a transparent resin layer having a thickness of 33 μm could be formed is indicated as “OK”; and a case in which a transparent resin layer having a thickness of 33 μm could not be formed is indicated as “NG”.

In Table 2, the term “Spectroscopic analysis 1” indicates the spectroscopic characteristics (transmissivity) of the transparent resin layer obtained after the transparent resin layer having a film thickness of 25 μm was heated for 5 minutes at 265° C.; and the term “Spectroscopic analysis 2” indicates the spectroscopic characteristics (transmissivity) of the transparent resin layer obtained after the transparent resin layer having a film thickness of 25 μm was heated for 60 minutes at 200° C. Data for the spectroscopic analysis 1 are absent for Comparative Examples 1 and 2 because the analysis could not be performed because numerous cracks were generated on the surface of the layer after heating.

Furthermore, the column “Extinction coefficient” in Table 2 indicates the molar absorption coefficients (c) at a wavelength of 365 nm of the various polymerization initiators used. For example, “(A) 19.5” means that the molar absorption coefficient (mol⁻¹·L·cm⁻¹) of (A) IRGACURE 184 is 19.5 mol⁻¹·L·cm⁻¹, and the values for (B) to (F) in the column “Extinction coefficient” also similarly represent the molar absorption coefficients of the polymerization initiators represented by (B) to (F).

Meanwhile, the molar absorption coefficients of the various initiators were calculated by preparing respective acetonitrile solutions of the initiators having the following concentrations, and measuring the absorbance.

(A) IRGACURE 184 7.15×10⁻³ mol/L

(B) Darocur 1173 6.21×10³ mol/L

(C) Darocur TPO 2.04×10⁻³ mol/L

(D) IRGACURE 819 1.98×10⁻³ mol/L

(E) IRGACURE OXE 01 1.17×10⁻³ mol/L

(F) C-1 9.55×10⁻⁴ mol/L

Acetonitrile solutions prepared at the concentrations described above were each introduced into a glass cell having a width of 1 cm, and the absorbance was measured using a UV-Vis-NIR spectrometer (CARY 5000) manufactured by Agilent Technologies, Inc. The molar absorption coefficient (mol^{-l}·L·cm⁻¹) was calculated by applying the absorbance to the following formula.

$$ɛ = \frac{A}{cl}$$

In the above formula, ε represents the molar absorption coefficient (mol^{-l}·L·cm⁻¹), A represents the absorbance; c represents the concentration (mol/L); and 1 represents the optical path length (cm).

TABLE 2

| | Composition | | | | |
|---|---|---|---|---|---|
| | | Extinction coefficient | | Polymerizable | Viscosity |
| | Polymerization initiator | (mol⁻¹ · L · cm⁻¹) | Polymer | compound | (mPa · s) |
| Example 1 | (A) IRGACURE 184 | (A) 19.5, (B) 10.9, (C) | B-1 | A-1 | 415 |
| | (B) Darocur 1173 | 456 | | | |
| | (C) Darocur TPO | | | | |
| Example 2 | (A) IRGACURE 184 | (A) 19.5, (C) 456 | B-1 | A-1 | 416 |
| | (C) Darocur TPO | | | | |
| Example 3 | (A) IRGACURE 184 | (A) 19.5, (D) 868 | B-1 | A-1 | 416 |
| | (D) IRGACURE 819 | | | | |
| Example 4 | (A) IRGACURE 184 | (A) 19.5 | B-1 | A-1 | 417 |
| Example 5 | (B) Darocur 1173 | (B) 10.9 | B-1 | A-1 | 413 |
| Example 6 | (A) IRGACURE 184 | (A) 19.5, (C) 456 | B-1 | A-4 | 871 |
| | (C) DarocurTPO | | | | |
| Example 7 | (A) IRGACURE 184 | (A) 19.5, (C) 456 | B-1 | A-4 | 1273 |
| | (C) Darocur TPO | | | | |
| Example 8 | (C) Darocur TPO | (C) 456 | B-1 | A-1 | 415 |
| Example 9 | (D) IRGACURE 819 | (D) 868 | B-1 | A-1 | 415 |
| Comparative | (E) IRGACURE OXE 01 | (E) 2932 | Cyclomer | A-1 | 420 |
| Example 1 | | | P-ACA | | |
| Comparative | (E) IRGACURE OXE 01 | (E) 2932 | B-1 | A-1 | 415 |
| Example 2 | | | | | |
| Comparative | (F) C-1 | (F) 1706 | B-1 | A-1 | 416 |
| Example 3 | | | | | |

| | Evaluation | | | | | |
|---|---|---|---|---|---|---|
| | | | | | | Pattern |
| | 25 μm | 30 μm | 33 μm | | | forming |
| | film | film | film | Spectroscopic | Spectroscopic | properties |
| | thickness | thickness | thickness | analysis 1 | analysis 2 | 50 μm |
| Example 1 | OK | OK | OK | 95% | 96% | A |
| Example 2 | OK | OK | OK | 95% | 96% | A |
| Example 3 | OK | OK | OK | 93% | 95% | A |
| Example 4 | OK | OK | OK | 98% | 98% | B |
| Example 5 | OK | OK | OK | 98% | 98% | B |
| Example 6 | OK | OK | OK | 95% | 96% | A |
| Example 7 | OK | OK | OK | 95% | 96% | A |
| Example 8 | OK | OK | OK | 90% | 86% | B |
| Example 9 | OK | OK | OK | 90% | 86% | B |
| Comparative | OK | OK | OK | — | 65% | C |
| Example 1 | | | | | | |
| Comparative | OK | OK | OK | — | 80% | C |
| Example 2 | | | | | | |
| Comparative | OK | OK | OK | 47% | 47% | C |
| Example 3 | | | | | | |

The structures of the compounds described in Table 2 are shown below.

Meanwhile, “Cyclomer P-ACA” means CYCLOMER P-ACA (230 AA) manufactured by Daicel Chemical Industries, Ltd.

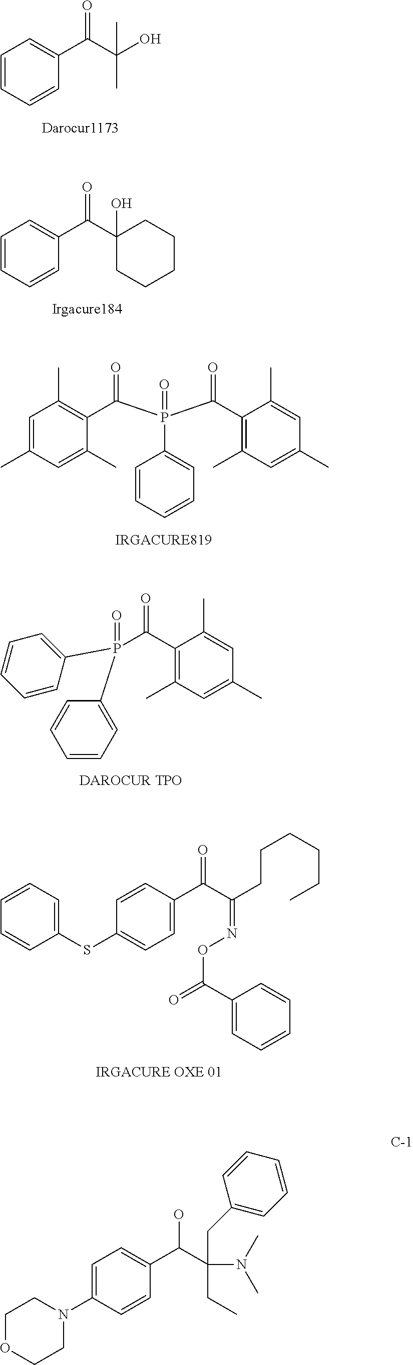

As shown in Table 2, in Examples 1 to 9 that used the compositions for forming a transparent resin layer of the invention, thick films could be produced, and it was confirmed that the thick films exhibited excellent patterning performance, underwent no coloration after a heating treatment, and had excellent spectroscopic characteristics.

On the other hand, in Comparative Examples 1, 2 and 3 that did not use predetermined polymerization initiators, it was confirmed that coloration occurred, and the films had inferior spectroscopic characteristics and inferior patterning properties.

Meanwhile, in Comparative Examples 1 and 2, the oxime-based photopolymerization initiator described in JP2010-078729A was used.

The transparent resin layers of Comparative Examples 1 and 2 were heated on a hot plate at 265° C. for 5 minutes, and cracks were observed in an area of about 10% to 100% of the film surface. In other Examples and Comparative Examples, cracks in a film area of 10% or more were not observed.

### Examples 10 to 18

Transparent resin layers of Examples 10 to 18 were formed according to the same procedure as that of Examples 1 to 9, except that the polymer B-1 was changed to polymer B-2, and various evaluations were performed. As a result, excellent results similar to those of Examples 1 to 9 were obtained.

### Examples 19 to 27

Transparent resin layers of Examples 19 to 27 were formed according to the same procedure as that of Examples 1 to 9, except that the polymer B-1 was changed to the exemplary polymer (ED1) described above, and various evaluations were performed. As a result, excellent results similar to those of Examples 1 to 9 were obtained.

### Examples 28 to 31

Transparent resin layers of Examples 28 to 31 were formed according to the same procedure as that of Example 6, except that the contents of the polymer and the polymerizable compound were changed as described below, and various evaluations were performed. As a result, excellent results similar to those of Examples 1 to 9 were obtained.

### Example 28

| | |
|---|---|
| Polymer B-1 a 60% propylene glycol-1-monomethyl | 49.63 parts by mass |
| ether-2-acetate (hereinafter, also referred | |
| go as PGMEA) solution | |
| Polymerizable compound (A-1) | 29.78 parts by mass |
| Polymerization initiators (IRGACURE 184) | 3.001 parts by mass |
| (Darocur TPO) | 0.429 parts by mass |
| Silane coupling agent ((N-2-(aminoethyl)-3- | 0.31 parts by mass |
| aminopropylmethyldimethoxysilane)) a 1% | |
| cyclohexanone solution | |
| Polymerization initiator (p-methoxyphenol) | 0.02 parts by mass |
| Surfactant (MEGAFAC F-781F manufactured | 0.87 parts by mass |
| by DIC Corp.) a 0.2% propylene | |
| glycol-1-monomethyl ether-2-acetate | |
| solution | |
| Propylene glycol-1-monomethyl ether-2-acetate | 15.96 parts by mass |

### Example 29

| | |
|---|---|
| Polymer B-1 a 60% propylene glycol-1-monomethyl | 55.14 parts by mass |
| ether-2-acetate (hereinafter, also referred | |
| to as PGMEA) solution | |
| Polymerizable compound (A-1) | 26.47 parts by mass |
| Polymerization initiators (IRGACURE 184) | 3.001 parts by mass |
| (Darocur TPO) | 0.429 parts by mass |
| Silane coupling agent ((N-2-(aminoethyl)-3- | 0.31 parts by mass |
| aminopropylmethyldimethoxysilane)) a 1% | |
| cyclohexanone solution | |
| Polymerization inhibitor (p-methoxyphenol) | 0.02 parts by mass |
| Surfactant (MEGAFAC F-781F manufactured by | 0.87 parts by mass |
| DIC Corp.) a 0.2% propylene glycol-1-monomethyl | |
| ether-2-acetate solution | |
| Propylene glycol-1-monomethyl ether-2-acetate | 13.76 parts by mass |

### Example 30

| | |
|---|---|
| Polymer B-1 a 60% propylene glycol-1-monomethyl | 62.03 parts by mass |
| ether-2-acetate (hereinafter, also referred | |
| to as PGMEA) solution | |
| Polymerizable compound (A-1) | 22.33 parts by mass |
| Polymerization initiators (IRGACURE 184) | 3.001 parts by mass |
| (Darocur TPO) | 0.429 parts by mass |
| Silane coupling agent ((N-2-(aminoethyl)-3- | 0.31 parts by mass |
| aminopropylmethyldimethoxysilane)) a 1% | |
| cyclohexanone solution | |
| Polymerization inhibitor (p-methoxyphenol) | 0.02 parts by mass |
| Surfactant (MEGAFAC F-781F manufactured by | 0.87 parts by mass |
| DIC Corp.) a 0.2% propylene glycol-1-monomethyl | |
| ether-2-acetate solution | |
| Propylene glycol-1-monomethyl ether-2-acetate | 11.01 parts by mass |

### Example 31

| | |
|---|---|
| Polymer B-1 a 60% propylene glycol-1-monomethyl | 70.89 parts by mass |
| ether-2-acetate (hereinafter, also referred | |
| to as PGMEA) solution | |
| Polymerizable compound (A-1) | 22.33 parts by mass |
| Polymerization initiators (IRGACURE 184) | 3.001 parts by mass |
| (Darocur TPO) | 0.429 parts by mass |
| Silane coupling agent ((N-2-(aminoethyl)-3- | 0.31 parts by mass |
| aminopropylmethyldimethoxysilane)) a 1% | |
| cyclohexanone solution | |
| Polymerization inhibitor (p-methoxyphenol) | 0.02 parts by mass |
| Surfactant (MEGAFAC F-781F manufactured by | 0.87 parts by mass |
| D1C Corp.) a 0.2% propylene glycol-1-monomethyl | |
| ether-2-acetate solution | |
| Propylene glycol-1-monomethyl ether-2-acetate | 2.15 parts by mass |

### Examples 32 to 35

Transparent resin layers of Examples 32 to 35 were formed according to the same procedure as that of Examples 28 to 31, except that the surfactant was changed to NCW-101 manufactured by Wako Pure Chemical Industries, Ltd., and various evaluations were performed. As a result, excellent results similar to those of Examples 1 to 9 were obtained.

[Evaluation of Multilayer Coating]

Examples 6, 7, and 28 to 35 were further subjected to an evaluation of multilayer coating.

Each of the compositions for forming a transparent resin layer of Examples 6, 7, and 28 to 35 was applied on a soda glass plate (75 mm×75 mm square, thickness 1.1 mm) by a spin coating method, and subsequently, the soda glass plate was heated on a hot plate for 2 minutes at 100° C. Thus, a coating film was obtained (prebaking). This coating film was exposed at 400 mJ/cm² using an ultrahigh pressure mercury lamp “USH-500BY” manufactured by Ushio, Inc. Thereby, a first transparent cured layer (transparent resin layer) (final film thickness: 10 μm) was obtained.

On the first cured layer, a second transparent cured layer (final film thickness: 10 μm) was obtained in the same manner as in the case of the first layer. Then, the multilayer structure was post-baked by heating the substrate on a hot plate for 5 minutes at 200° C. As a result, it was found that all of the compositions for forming a transparent resin layer could form multilayer films satisfactorily. It was confirmed that the multilayer films thus obtained had an excellent surface state and uniform film thicknesses.

The compositions for forming a transparent resin layer of Examples 6, 7, and 28 to 35 were subjected to prebaking and exposure in the same manner as described above, and a first transparent cured layer (transparent resin layer) (final film thickness: 10 μm) and a second transparent cured layer (final film thickness: 10 μm) were obtained for each. Furthermore, a third transparent cured layer (final film thickness: 10 μm) was formed (total 30 μm) on the second cured layer in the same manner as in the case of the first layer, and the assembly was subjected to post-baking as described above.

As a result, it was found that all of the compositions for forming a transparent resin layer could form multilayer films satisfactorily. It was confirmed that the multilayer films thus obtained had an excellent surface state and uniform film thicknesses.

In regard to these Examples, it was also confirmed that pattern formation after exposure and development could be achieved in all of the layers.

What is claimed is:

1. A composition for forming a transparent resin layer, the composition comprising:
a polymerization initiator having a molar absorption coefficient (ε) at a wavelength of 365 nm of 1000 mol⁻¹·L·cm⁻¹ or less;
a polymerizable compound;
a polymer; and
a solvent.

2. The composition for forming a transparent resin layer according to claim 1, wherein the polymerization initiator does not contain an amino group.

3. The composition for forming a transparent resin layer according to claim 1, wherein the polymerization initiator includes at least one selected from the group consisting of an α-hydroxyacetophenone-based compound and a phosphine-based compound.

4. The composition for forming a transparent resin layer according to claim 1, wherein the polymerization initiator includes both an α-hydroxyacetophenone-based compound and a phosphine-based compound.

5. The composition for forming a transparent resin layer according to claim 4, wherein the phosphine-based compound is included in an amount of 5 to 30 parts by mass with respect to 100 parts by mass of the α-hydroxyacetophenone-based compound.

6. The composition for forming a transparent resin layer according to claim 1, comprising a polymer formed by polymerizing a monomer component including a compound represented by the following Formula (ED) as the polymer, 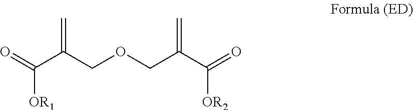
wherein in Formula (ED), R₁ and R₂ each independently represent a hydrogen atom or a hydrocarbon group having 1 to 25 carbon atoms which may have a substituent.

7. The composition for forming a transparent resin layer according to claim 1, comprising a bifunctional or higher-functional (meth)acrylate compound having at least an acid group, as the polymerizable compound.

8. The composition for forming a transparent resin layer according to claim 3, wherein the α-hydroxyacetophenone-based compound includes a compound represented by Formula (1), 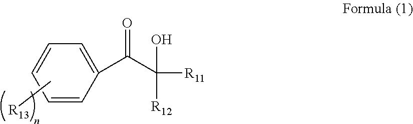
wherein in Formula (1), R₁₁ and R₁₂ each independently represent a hydrogen atom, an alkoxy group, or an alkyl group which may have a substituent; R₁₃ represents a hydrocarbon group which may contain a heteroatom; n represents an integer from 0 to 5; R₁₁ and R₁₂ may be bonded to each other and form a cyclic structure; and in the case where there are plural R₁₃'s, R₁₃'s may be respectively identical to or different from each other.

9. The composition for forming a transparent resin layer according to claim 3, wherein the phosphine-based compound includes acylphosphine oxide.

10. The composition for forming a transparent resin layer according to claim 3, wherein the phosphine-based compound includes a compound selected from the group consisting of a compound represented by Formula (2) and a compound represented by Formula (3): 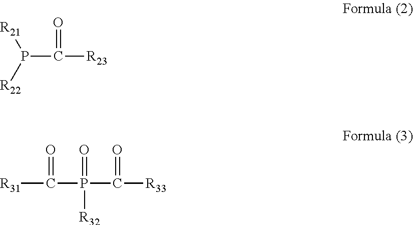
wherein in Formula (2), R₂₁ and R₂₂ each independently represent an aliphatic group, an aromatic group, an aliphatic oxy group, an aromatic oxy group, or a heterocyclic group; R₂₃ represents an aliphatic group, an aromatic group, or a heterocyclic group; and each of R₂₁ to R₂₃ may further have a substituent; and
in Formula (3), R₃₁ and R₃₃ each independently represent an alkyl group, an aryl group, or a heterocyclic group; R₃₂ represents an alkyl group, an aryl group, an alkoxy group, an aryloxy group, or a heterocyclic group; and each of R₃₁ to R₃₃ may further have a substituent.

11. The composition for forming a transparent resin layer according to claim 1, wherein the polymerization initiator includes at least one selected from the group consisting of 2-hydroxy-2-methyl-1-phenylpropan-1-one, bis(2,4,6-trimethylbenzoyl)phenylphosphine oxide, bis(2,6-dimethoxybenzoyl)-2,4,4-trimethylpentylphosphine oxide, 1-hydroxycyclohexyl phenyl ketone, and diphenyl(2,4,6-trimethylbenzoyl)phosphine oxide.

12. The composition for forming a transparent resin layer according to claim 1, further comprising at least one selected from the group consisting of an ultraviolet absorber, an adhesion improving agent, a polymerization inhibitor, and a surfactant.

13. The composition for forming a transparent resin layer according to claim 1, wherein the content of the solvent is 1% by mass to 50% by mass with respect to the total mass of the composition for forming a transparent resin layer.

14. A transparent resin layer formed by curing the composition for forming a transparent resin layer according to claim 1.

15. A solid imaging element comprising a transparent resin layer formed by curing the composition for forming a transparent resin layer according to claim 1.

16. An optoelectronics device comprising a transparent resin layer formed by curing the composition for forming a transparent resin layer according to claim 1.

17. A composition for forming a transparent resin layer, the composition comprising:
a polymerization initiator having a molar absorption coefficient (ε) at a wavelength of 365 nm of 1000 mol⁻¹·L·cm⁻¹ or less;
a polymerizable compound;
a polymer; and
a solvent,
wherein the polymerization initiator includes at least one selected from the group consisting of an α-hydroxyacetophenone-based compound and a phosphine-based compound, and, does not contain an amino group.

18. The composition for forming a transparent resin layer according to claim 17, wherein the polymerization initiator includes both an α-hydroxyacetophenone-based compound and a phosphine-based compound.

19. The composition for forming a transparent resin layer according to claim 18, wherein the phosphine-based compound is included in an amount of 5 to 30 parts by mass with respect to 100 parts by mass of the α-hydroxyacetophenone-based compound.
